(19) United States
(12) Patent Application Publication
(10) Pub. No.: US 2025/0248042 A1
(43) Pub. Date: Jul. 31, 2025

(54) SEMICONDUCTOR DEVICES

(71) Applicant: SAMSUNG ELECTRONICS CO., LTD., Suwon-si (KR)

(72) Inventors: Gilsung Lee, Suwon-si (KR); Sunil Shim, Suwon-si (KR); Seung-Jun Lee, Suwon-si (KR); Soochan Chung, Suwon-si (KR)

(21) Appl. No.: 18/819,522

(22) Filed: Aug. 29, 2024

(30) Foreign Application Priority Data
Jan. 30, 2024 (KR) 10-2024-0014203

(51) Int. Cl. H10B 43/35; H10B 41/10; H10B 41/27; H10B 41/35; H10B 41/41; H10B 43/10; H10B 43/27; H10B 43/40

(52) U.S. Cl. CPC H10B 43/35; H10B 41/10; H10B 41/27; H10B 41/35; H10B 41/41; H10B 43/10; H10B 43/27; H10B 43/40

(57) ABSTRACT

A semiconductor device includes: a peripheral circuit structure and a cell structure stacked on the peripheral circuit structure, in which the peripheral circuit structure includes a first substrate on which circuit elements are located, the cell structure includes: a second substrate including one surface facing the first substrate and the other surface opposite the one surface; a gate stack structure including a plurality of interlayer insulating layers and a plurality of gate electrodes alternately stacked on the one surface of the second substrate; a plurality of channel structures penetrating the gate stack structure; and a separation structure penetrating at least a portion of the channel structure and at least a portion of the plurality of gate electrodes from the one surface of the second substrate, and the separation structure has a zigzag shape along a first direction and a second direction intersecting the first direction in a plane.

### CROSS-REFERENCE TO RELATED APPLICATION

This application claims priority to and the benefit of Korean Patent Application No. 10-2024-0014203, filed in the Korean Intellectual Property Office on Jan. 30, 2024, the entire contents of which are incorporated herein by reference.

### BACKGROUND

A semiconductor is a material belonging to an intermediate region between a conductor and a nonconductor, and refers to a material that conducts electricity under certain conditions. Various semiconductor devices may be manufactured by using these semiconductor materials, and for example, memory devices and the like may be manufactured. Memory devices may be categorized into volatile memory devices and non-volatile memory devices. For the non-volatile memory devices, the contents may not be erased even if the power is interrupted, so that the non-volatile memory devices may be used in various electronic devices, such as cell phones, digital cameras, and PCs.

Recently, as the storage capacity used for device operation has increased, it is necessary to improve the density of non-volatile memory devices. The density of memory devices arranged in two dimensions on a plane may be limited. Therefore, vertical non-volatile memory devices that are arranged in three dimensions have been proposed.

### SUMMARY

Some aspects of the present disclosure provide semiconductor devices with improved reliability, and electronic systems including the same.

Some aspects of the present disclosure provide a semiconductor device including: a peripheral circuit structure and a cell structure stacked on the peripheral circuit structure, in which the peripheral circuit structure includes a first substrate on which circuit elements are located, the cell structure includes: a second substrate including one surface facing the first substrate and the other surface opposite the one surface; a gate stack structure including a plurality of interlayer insulating layers and a plurality of gate electrodes alternately stacked on the one surface of the second substrate; a plurality of channel structures penetrating the gate stack structure; and a separation structure penetrating at least a portion of the channel structure and at least a portion of the plurality of gate electrodes from the one surface of the second substrate, and the separation structure has a zigzag shape along a first direction and a second direction intersecting the first direction in a plane.

Some aspects of the present disclosure provide a semiconductor device including: a peripheral circuit structure and a cell structure stacked on the peripheral circuit structure, in which the peripheral circuit structure includes a first substrate on which circuit elements are located, the cell structure includes: a second substrate including one surface facing the first substrate and the other surface opposite the one surface; a gate stack structure including a plurality of interlayer insulating layers and a plurality of gate electrodes including ground gate electrodes alternately stacked on the one surface of the second substrate; a plurality of channel structures penetrating the gate stack structure; and a separation structure penetrating at least a portion of the channel structure from the one surface of the second substrate, and separating the ground gate electrodes into a first portion and a second portion, the separation structure includes: a first extending portion extending in a first direction in a plane, a second extending portion extending in a second direction intersecting the first direction in a plane, and a point where the first extending portion and the second extending portion meet overlaps the channel structure in a thickness direction of the second substrate.

Some aspects of the present disclosure provide an electronic system including a semiconductor device, the electronic system including: a main substrate; a semiconductor device on the main substrate; and a controller electrically connected to the semiconductor device on the main substrate, in which the semiconductor device includes: a peripheral circuit structure including a first substrate; a cell structure stacked on top of the peripheral circuit structure and including input and output connection wires electrically connected to the peripheral circuit structure; and an input/output pad electrically connected to the input/output connection wires extending into the cell structure, the cell structure includes: a second substrate including one surface facing the first substrate and the other surface opposite the one surface; a gate stack structure including a plurality of interlayer insulating layers and a plurality of gate electrodes alternately stacked on the one surface of the second substrate; a plurality of channel structures penetrating the gate stack structure; and a separation structure penetrating at least a portion of the channel structure and at least a portion of the plurality of gate electrodes from the one surface of the second substrate, and the separation structure has a zigzag shape along a first direction and a second direction intersecting the first direction in a plane.

### BRIEF DESCRIPTION OF THE DRAWINGS

FIG. 1 is a schematic top plan view of an example of a semiconductor device.

FIG. 2 is a cross-sectional view taken along line A-A′ of FIG. 1.

FIG. 3 is a cross-sectional view of enlarged region P1 of FIG. 2.

FIG. 4 is a cross-sectional view of region P1 of FIG. 2.

FIG. 5 is an enlarged plan view of region P2 of FIG. 1.

FIGS. 6 to 11 are cross-sectional views corresponding to region P2 of FIG. 1.

FIGS. 12 and 13 are cross-sectional views corresponding to region P1 of FIG. 2.

FIG. 14 is a top plan view illustrating an example of a semiconductor device.

FIG. 15 is a cross-sectional view illustrating an example of a semiconductor device.

FIGS. 16 to 18 are cross-sectional views illustrating intermediate operations of an example of a method of manufacturing a semiconductor device.

FIGS. 19 to 44 are cross-sectional views corresponding to region P3 of FIG. 18, illustrating examples of operations of fabricating semiconductor devices.

FIG. 45 is a perspective view schematically illustrating an example of an electronic system including a semiconductor device.

FIG. 46 is a diagram schematically illustrating an example of an electronic system including a semiconductor device.

FIG. 47 is a cross-sectional view schematically illustrating an example of a semiconductor package.

### DETAILED DESCRIPTION

In the following detailed description, various examples have been illustrated and described. It will be understood that the scope of the present disclosure is not limited to the specific described examples and that various modifications and combinations may be made. Like reference numerals designate like elements throughout the specification.

In addition, the size and thickness of each configuration illustrated in the drawings are arbitrarily illustrated for understanding and ease of description, but the present disclosure is not limited thereto. In the drawings, the thickness of layers, films, panels, areas, regions, and the like, may be exaggerated for clarity.

It will be understood that when an element such as a layer, film, region, or substrate is referred to as being “on” another element, it may be directly on the other element or intervening elements may also be present. In contrast, when an element is referred to as being “directly on” another element, there are no intervening elements present. Also, being “on” or “above” a reference portion means being above or below the reference portion and does not necessarily mean being “on” or “above” the reference portion in the opposite direction of gravity.

In addition, unless explicitly described to the contrary, the word “comprise”, and variations such as “comprises” or “comprising”, will be understood to imply the inclusion of stated elements but not the exclusion of any other elements.

Further, in the entire specification, when a drawing is referred to as “in a plan view”, it means when a target part is viewed from above, and when it is referred to as “in a cross-sectional view”, it means when the cross-section obtained by cutting a target part vertically is viewed from the side.

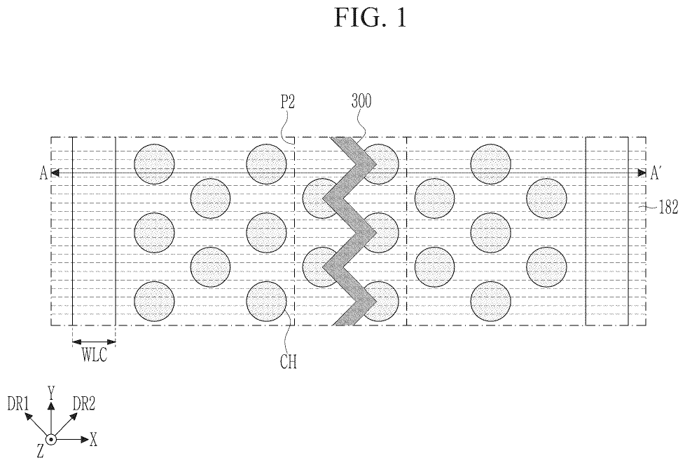

Hereinafter, an example of a semiconductor device will be described with reference to FIGS. 1 to 5.

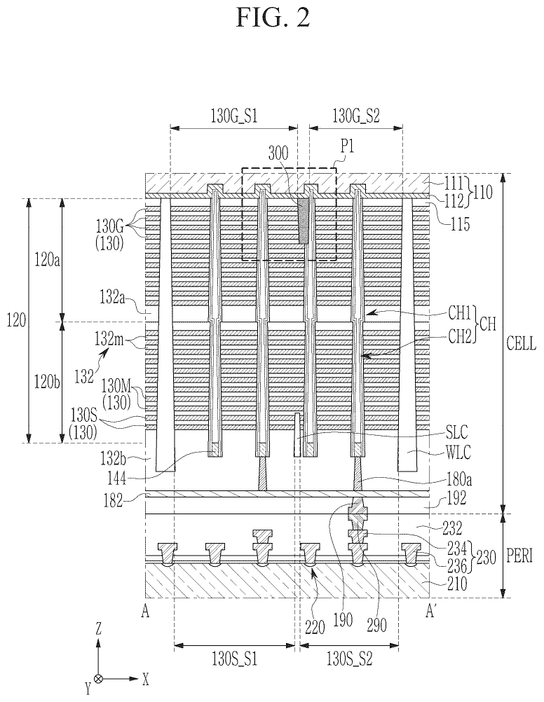

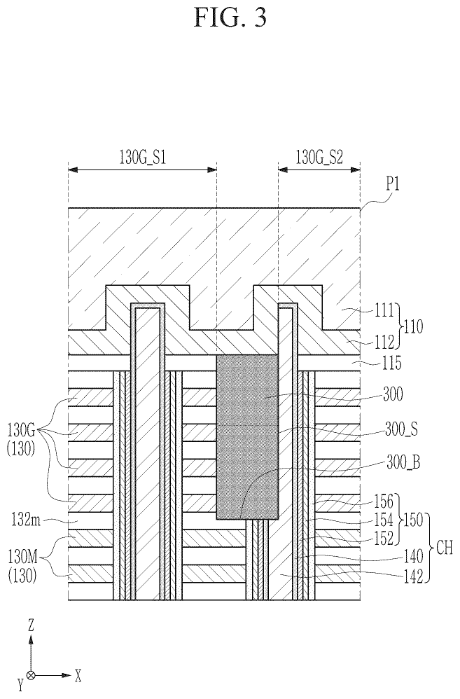

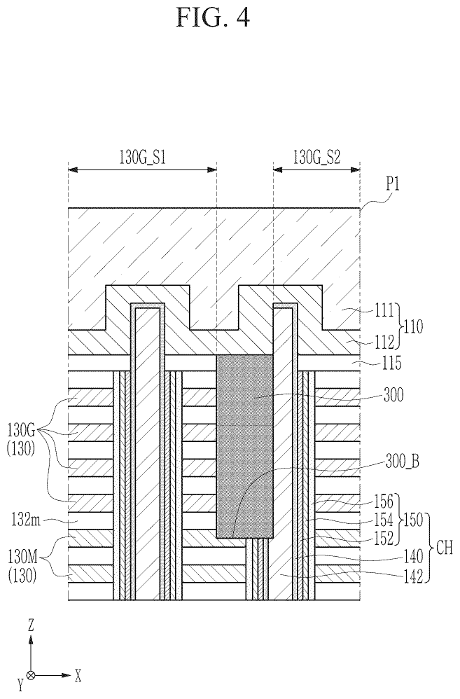

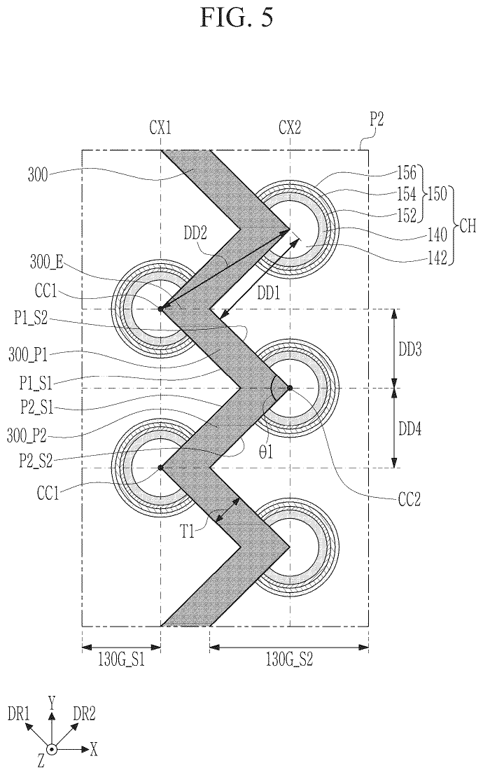

FIG. 1 is a schematic top plan view of a semiconductor device. FIG. 2 is a cross-sectional view taken along line A-A′ of FIG. 1. FIG. 3 is a cross-sectional view of enlarged region P1 of FIG. 2. FIG. 4 is a cross-sectional view of region P1 of FIG. FIG. 5 is an enlarged plan view of region P2 of FIG. 1.

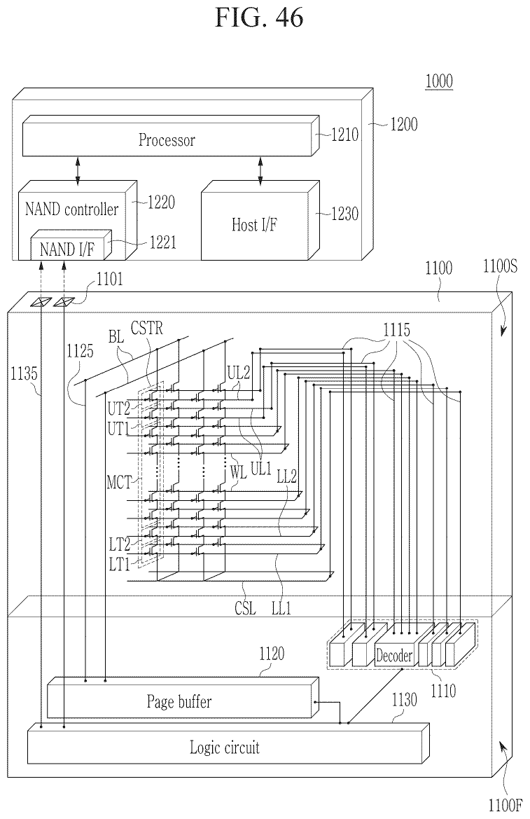

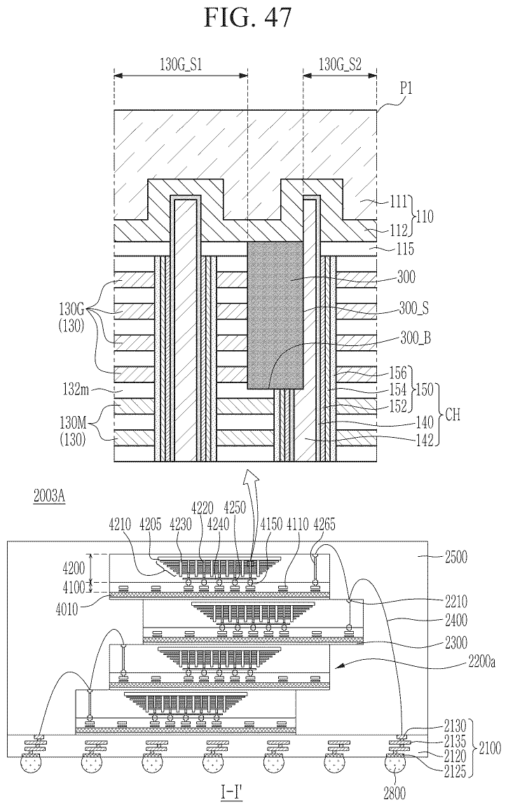

Referring first to FIGS. 1 and 2, a semiconductor device according to some implementations includes a cell structure CELL and a peripheral circuit structure PERI that are vertically stacked. The cell structure CELL and the peripheral circuit structure PERI may be bonded semiconductor devices in a chip to chip (C2C) structure bonded by a wafer bonding method (for example, hybrid joining). In some implementations, the peripheral circuit structure PERI and the cell structure CELL are portions corresponding to a first structure 1100F and a second structure 1100S, respectively, of a semiconductor device 1100 included in an electronic system 1000 illustrated in FIG. 46. In some implementations, the peripheral circuit structure PERI and the cell structure CELL are portions including a first structure 4100 and a second structure 4200, respectively, of a semiconductor chip 2200 illustrated in FIG. 47.

The cell structure CELL may be stacked on top of the peripheral circuit structure PERI. For example, the cell structure CELL may be located on an upper end of the peripheral circuit structure PERI. However, the relative positions are not limited thereto, and in some implementations, for example, the semiconductor device is located on a single substrate with the cell structure CELL and the peripheral circuit structure PERI separated. For example, the cell structure CELL and the peripheral circuit structure PERI may not overlap each other vertically. In some implementations, the cell structure CELL is located at the bottom end of the peripheral circuit structure PERI.

The peripheral circuit structure PERI of the semiconductor device may include a first substrate 210, circuit elements 220 located on the first substrate 210, first and second contact vias 234 and 236, and a first junction structure 290.

The first substrate 210 may include a front side and a back side that face each other. The front side of the first substrate 210 may face the cell structure CELL. The back side of the first substrate 210 may face the cell structure CELL. The first substrate 210 may have separate element separation layers formed to define an active region. Source/drain regions containing impurities may be located in a portion of the active region. The first substrate 210 may be a semiconductor substrate including a semiconductor material. For example, the first substrate 210 may be a semiconductor substrate made of a semiconductor material, or may be a semiconductor substrate in which a semiconductor layer formed on a base substrate. The first substrate 210 may be formed of monocrystalline or polycrystalline silicon, epitaxial silicon, germanium, or silicon-germanium, silicon on insulator (SOI), germanium on insulator (GOI), and/or the like.

The circuit elements 220 may be located on the first substrate 210. The circuit elements 220 may include various circuit elements that control the operation of the memory cell structure provided in the cell structure CELL. For example, the circuit elements 220 may include peripheral circuit structures, such as a decoder circuit (reference numeral 1110 in FIG. 46), a page buffer (reference numeral 1120 in FIG. 46), a logic circuit (reference numeral 1130 in FIG. 46), and/or the like. The circuit element 220 may include, for example, but is not limited to, a transistor. For example, the circuit elements 220 may include active elements, such as transistors, as well as passive elements, such as capacitors, resistors, and inductors.

A first inter-wire insulating layer 232 may be located on the circuit element 220 on the first substrate 210. First and second contact vias 236 and 234 may penetrate (extend through) the first inter-wire insulating layer 232 and be connected to the circuit element 220. An electrical signal may be applied to the circuit element 220 by the first and second contact vias 236 and 234. Each of the first and second contact vias 236 and 234 may be located in a single or plurality of layers.

In some implementations, one surface of the peripheral circuit structure PERI is bonded with one surface of the cell structure CELL by hybrid joining. For example, one surface of the peripheral circuit structure PERI adjacent to the cell structure CELL may be a junction surface with the cell structure CELL, and may be configured with a first junction structure 290 and a portion of the first inter-wire insulating layer 232. The first junction structure 290 may be electrically connected to the circuit element 220 via the first and second contact vias 236 and 234. For example, the first junction structure 290 of the peripheral circuit structure PERI and the second junction structure 190 of the cell structure CELL may be bonded in a direct contact state to form metal junction. Further, a portion of the first inter-wiring insulating layer 232 of the peripheral circuit structure PERI and a portion of the second inter-wiring insulating layer 192 of the cell structure CELL may be bonded. However, the present disclosure is not limited thereto, and, for example, a separate junction insulating layer may be provided between the first inter-wiring insulating layer 232 and the second inter-wiring insulating layer 192, and portions of the junction insulating layers may be bonded to each other.

The first junction structure 290 may be made of copper, aluminum, tungsten, nickel, gold, tin, manganese, cobalt, titanium, tantalum, ruthenium, or an alloy thereof. In some implementations, the first junction structure 290 includes copper at least at the junction surface, such that the metal junction of the peripheral circuit structure PERI and the cell structure CELL are configured as a copper-to-copper junction. However, various suitable materials may be used for the first junction structure 290.

The first junction structure 290 of the peripheral circuit structure PERI and the second junction structure 190 of the cell structure CELL may be bonded to provide an electrical connection path between the peripheral circuit structure PERI and the cell structure CELL. For example, a bit line 182 and/or gate electrodes 130 connected to a channel structure CH, which will be described later, may be electrically connected to the circuit elements 220 of the peripheral circuit structure PERI via the first and second contact vias 236 and 234.

The cell structure CELL may include a second substrate 110, a gate stack structure 120 located on a bottom surface of the second substrate 110, a channel structure CH penetrating the gate stack structure 120, and a separation structure 300 penetrating at least a portion of the gate stack structure 120. Here, the gate stack structure 120 may include a plurality of alternately stacked gate electrodes 130 and a cell insulating layer 132.

The second substrate 110 may have a top surface extending in a first direction (X direction) and a second direction (Y direction). The second substrate 110 may include a semiconductor material, such as a IV group semiconductor, a III-V group compound semiconductor, or a II-VI group compound semiconductor. For example, the IV group semiconductor may include silicon, germanium, or silicon-germanium. The second substrate 110 may be provided as a bulk wafer, an epitaxial layer, a silicon on insulator (SOI) layer, or a semiconductor on insulator (SeOI) layer. However, the present disclosure is not limited thereto.

In some implementations, the second substrate 110 includes one surface and another surface that are opposite each other. The one surface of the second substrate 110 may mean a surface facing the peripheral circuit structure PERI. The other surface of the second substrate 110 may mean a surface opposite the one surface of the second substrate 110. Here, the one surface of the second substrate 110 may be referred to as the front side of the second substrate 110 or the top surface of the second substrate 110, and the other surface of the second substrate 110 may be referred to as the back side of the second substrate 110 or the bottom surface of the second substrate 110.

The second substrate 110 may include a common source electrode 112 and an insulating pattern 111. The common source electrode 112 may cover the gate stack structure 120, which will be described later. For example, the common source electrode 112 may cover a substrate insulating layer 115, and the channel structure CH. The common source electrode 112 may be connected with a channel layer 140 of the channel structure CH. The common source electrode 112 may be provided as a common source line (for example, CSL in FIG. 46) of a non-volatile memory device. The common source electrode 112 may include, for example, but is not limited to, impurity-doped polycrystalline silicon, metal, or combinations thereof.

The insulating pattern 111 may be located on the common source electrode 112. The insulating pattern 111 may include, for example, but is not limited to, at least one of silicon oxide, silicon nitride, silicon nitric oxide, and silicon carbide. For example, the insulating pattern 111 may include, for example, flowable oxide (FOX), tonen silazen (TOSZ), undoped silica glass (USG), borosilica glass (BSG), phosphosilica glass (PSG), boroPhosphosilica glass (BPSG), plasma enhanced tetra ethyl ortho silicate (PE-TEOS), fluoride silicate glass (FSG), high density plasma (HDP), plasma enhanced oxide (PEOX), flowable CVD (FCVD), or any combination thereof.

The gate stack structure 120 may be located on the front side of the second substrate 110. For example, the gate stack structure 120 may be located on one surface of the second substrate 110 facing the first substrate 210. The gate stack structure 120 may be located between the first substrate 210 and the second substrate 110. The gate stack structure 120 may include a plurality of gate electrodes 130 and a plurality of cell insulating layers 132 stacked alternately each other.

The plurality of gate electrodes 130 may include ground gate electrodes 130G that form gates of ground select transistors and memory gate electrodes 130M that form a plurality of memory cells. The capacity of the semiconductor device may determine the number of memory gate electrodes 130M forming the memory cells. For example, as illustrated in FIG. 2, the top four gate electrodes 130 of the plurality of gate electrodes 130 may be ground gate electrodes 130G. However, the present disclosure is not limited thereto, and the ground gate electrode 130G may be formed of three or fewer layers of the plurality of gate electrodes 130. In some implementations, at least some of the ground gate electrodes 130G are dummy gate electrodes.

In some implementations, at least some of the ground gate electrodes 130G are spaced apart from each other (e.g., laterally in the X and/or Y directions). For example, as illustrated in FIGS. 1 and 2, the ground gate electrodes 130G may be separated into a first portion 130G_S1 and a second portion 130G_S2 by the separation structure 300, which will be described later. The first portion 130G_S1 of the ground gate electrode 130G and the second portion 130G_S2 of the ground gate electrode 130G may be located while being spaced apart in the first direction (X direction). The first portion 130G_S1 of the ground gate electrode 130G may not be electrically connected with (may be electrically disconnected from) the second portion 130G_S2 of the ground gate electrode 130G.

In addition, at least some of the plurality of gate electrodes 130 may further include select gate electrodes 130S that form a gate of a string select transistor. For example, the select gate electrode 130S may be located under the memory gate electrodes 130M. The select gate electrode 130S may be a string select line forming a string select transistor (see “UT1 and UT2” in FIG. 46). In FIG. 2, it is illustrated that the select gate electrode 130S is formed of two layers, but the present disclosure is not limited to that number of layers.

At least some of the select gate electrodes 130S may be spaced apart from each other (e.g., laterally in the X and/or Y directions). For example, as illustrated in FIG. 2, the select gate electrode 130S may be separated into a first portion 130S_S1 and a second portion 130S_S2 by a select separation pattern SLC, which will be described later. The first portion 130S_S1 of the select gate electrode 130S and the second portion 130S_S2 of the select gate electrode 130S may be located while being spaced apart in the first direction (X direction). The first portion 130S_S1 of the select gate electrode 130S may not be electrically connected with the second portion 130S_S2 of the select gate electrode 130S.

The plurality of gate electrodes 130 may include gate electrodes that are located under of the ground gate electrode 130G and configure erase transistors utilized for erase operation using a gate induced drain leakage (GIDL) phenomenon. Additionally, some of the plurality of gate electrodes 130 (for example, memory gate electrodes 130M adjacent to ground gate electrodes 130G) may be dummy gate electrodes. In some implementations, at least some of the ground gate electrodes 130G are dummy gate electrodes.

The gate electrode 130 may include various conductive materials. For example, the gate electrodes 130 may include metallic materials, such as tungsten (W), copper (Cu), and aluminum (Al), polycrystalline silicon, metal nitrides (for example, titanium nitride (TiN), and tantalum nitride (TaN)), or combinations thereof.

The cell insulating layers 132 may be located between the plurality of gate electrodes 130 and may be alternately located in the third direction (Z direction) with the plurality of gate electrodes 130. Similar to the plurality of gate electrodes 130, the cell insulating layers 132 may be spaced apart from each other in the third direction (Z direction) from the front side of the second substrate 110.

The cell insulating layer 132 may include an interlayer insulating layer 132m located between two neighboring gate electrodes 130 within the gate stack structure 120, and a substrate insulating layer 115 located on top of the gate stack structure 120 and contacting the front side of the second substrate 110. Further, the cell insulating layer 132 may include a plurality of cell region insulating layers 132a and 132b covering a bottom surface of each of the plurality of gate stack structures 120a and 120b. The cell insulating layer 132 may include a variety of insulating materials. For example, the cell insulating layers 132 may include silicon oxide, silicon nitride, silicon nitric oxide, low dielectric material having a lower dielectric constant than the silicon oxide, or a combination thereof.

The semiconductor device may further include a gate dielectric layer surrounding the plurality of gate electrodes 130. The gate dielectric layer may be located between the plurality of gate electrodes 130 and the cell insulating layer 132, and between the plurality of gate electrodes 130 and the channel structure CH.

The channel structures CHs may form a single memory cell string, and be spaced apart from each other in rows and columns on the front side of the second substrate 110. For example, the channel structures CHs may be arranged in a zigzag shape in a plane defined by the first direction (X direction) and the second direction (Y direction).

In some implementations, as illustrated in FIG. 1, the channel structures CHs are located in a zigzag shape defined between adjacent separation patterns WLCs by a plurality (for example, three) of channel structures CHs arranged in a first column and a plurality (for example, two) of channel structures CHs arranged in a second column. For example, the channel structures CHs may be arranged along a direction similar to a first diagonal direction DR1 intersecting the first direction (X direction) and the second direction (Y direction). Further, the channel structures CHs may be arranged along a direction similar to a second diagonal direction DR2 intersecting the first direction (X direction), the second direction (Y direction), and the first diagonal direction DR1. Here, the first diagonal direction DR1 may refer to a direction of extension of a first extended portion 300_P1 of the separation structure 300, which will be described later. Here, the second diagonal direction DR2 may refer to a direction of extension of a second extended portion 300_P2 of the separation structure 300, which will be described later. The channel structures CHs may be arranged in the directions similar to the direction of extension of the first extended portion 300_P1 of the separation structure 300 and the direction of extension of the second extended portion 300_P2 of the separation structure 300, which will be described later.

In FIG. 1, it is illustrated that the three channel structures CHs in the first column and the two channel structures CHs in the second column are arranged in the zigzag shape, but the present disclosure is not limited thereto. For example, four or more channel structures CHs may be arranged in a zigzag shape per column. In addition, it is illustrated that the channel structures CHs are arranged in eight columns between adjacent separation patterns WLC, but the present disclosure is not limited thereto. For example, the channel structures CHs may be arranged in 12 columns between adjacent separation patterns WLCs in the first direction (X direction).

The channel structures CHs may extend through the gate stack structure 120 in a cross direction (for example, a third direction (Z direction)) that is intersecting (for example, perpendicular to) the second substrate 110. Each of the channel structures CHs may have a columnar shape and may have a sloping lateral surface that becomes narrower as it becomes closer to the second substrate 110, depending on an aspect ratio, but the present disclosure is not limited thereto.

Referring to FIG. 3, the channel structure CH may include a channel layer 140 and a gate dielectric layer 150 located on the channel layer 140 between the gate electrode 130 and the channel layer 140. The channel structure CH may further include a core insulating layer 142 located on an interior (for example, center region) of the channel layer 140, but as another example, the channel structure CH may not be provided with a core insulating layer 142.

The gate dielectric layer 150 may include a tunneling layer 152, a charge storage layer 154, and a blocking layer 156, which are located in turn on a lateral surface of the channel layer 140. The channel structure CH may further include a channel pad 144 connected with the channel layer 140.

The channel layer 140 may include a semiconductor material, such as polycrystalline silicon. The core insulating layer 142 may include a variety of insulating materials. For example, the core insulating layer 142 may include silicon oxide, silicon nitride, silicon nitric oxide, or a combination thereof. The tunneling layer 152 may include an insulating material that allows tunneling of charge. For example, the tunneling layer 152 may include silicon oxide, silicon nitric oxide, and/or the like. The charge storage layer 154 is utilized as a data storage area and may include polycrystalline silicon, silicon nitride, and/or the like. The blocking layer 156 may include an insulating material that may prevent unwanted introduction of charge into the gate electrode 130. For example, the blocking layer 156 may include silicon oxide, silicon nitride, silicon nitric oxide, a high dielectric material having a higher dielectric constant than silicon oxide, or a combination thereof.

However, the materials, stacking structures, and the like of the channel layer 140, the core insulating layer 142, and the gate dielectric layer 150 may vary in different implementations and are not limited thereto.

As illustrated in FIGS. 2 and 3, the channel structure CH may include a portion that further protrudes toward the back side of the second substrate 110 than the top surface of the gate stack structure 120. For example, one end of the channel structure CH may be located between the front side and the back side of the common source electrode 112. At least a portion of the channel structure CH may overlap the second substrate 110 in a horizontal direction (for example, the first direction (X direction) and/or the second direction (Y direction)).

A portion of the gate dielectric layer 150 located at one end of the channel structure CH may be removed. The top surface of the channel layer 140 and/or the core insulating layer 142 may be located between the front side and the back side of the common source electrode 112. Accordingly, the portion of the channel layer 140 that overlaps the second substrate 110 in the horizontal direction (for example, first direction (X direction) and/or second direction (Y direction)) may be in contact with the common source electrode 112. For example, portions of the top surface and the lateral surface of the channel layer 140 may be in contact with the common source electrode 112. For example, a portion of the channel layer 140 may be provided within the common source electrode 112. In some implementations, at least portions of the channel layer 140 and the core insulating layer 142 located at one end of the channel structure CH are removed. For example, at least portions of the channel layer 140 and the core insulating layer 142 located above the separation structure 300, which will be described later, may be removed. Accordingly, the lateral surface of the core insulating layer 142 located on the separation structure 300, which will be described later, may be in contact with the common source electrode 112.

However, the present disclosure is not limited thereto, and the channel layer 140 of the semiconductor device may be in contact with a horizontal conductive layer located between the second substrate 110 and the gate stack structure 120. The horizontal conductive layer may be connected to the channel structure CH to function as a common source line.

The channel pad 144 (illustrated in FIG. 2) may be located on the bottom surface of the channel structure CH. The channel pad 144 may be electrically connected to the channel structure CH. For example, the channel pad 144 may be located on the bottom surface of the core insulating layer 142 and may be located to be connected with the channel layer 140. The channel pad 144 may include a conductive material, such as polycrystalline silicon doped with impurities, but the present disclosure is not limited thereto.

The gate stack structure 120 may include a plurality of gate stack structures 120a and 120b stacked one after the other on the back side of the second substrate 110, and the channel structure CH may include a plurality of channel structures CH1 and CH2 that penetrate the plurality of gate stack structures 120a and 120b. The number of gate electrodes 130 stacked may then be increased, thereby increasing the number of memory cells in a stable structure. While it is illustrated in the drawings that two gate stack structures 120 are provided, implementations are not limited thereto. Thus, the gate stack structure 120 may be formed of a single gate stack structure, or may include three or more gate stack structures.

Furthermore, the plurality of channel structures CH1 and CH2 forming one channel structure CH may have an interconnected form. Each of the plurality of channel structures CH1 and CH2 may have a sloping lateral surface such that, when viewed in cross-section, the width thereof narrows as it becomes closer to the second substrate 110 according to the aspect ratio. And, as illustrated in FIG. 2, a bent portion may be provided where the first channel structure CH1 and the second channel structure CH2 are connected due to the difference in widths, but the present disclosure is not limited thereto.

In FIG. 2, it is illustrated that the gate dielectric layer 150, the channel layer 140, and the core insulating layer 142 of the plurality of channel structures CH1 and CH2 have an integral structure formed by extending between the channel structures CH1 and CH2. However, implementations are not limited thereto, and the gate dielectric layer 150, the channel layer 140, and the core insulating layer 142 of the plurality of channel structures CH1 and CH2 may be formed separately from each other and electrically connected to each other. Further, a separate channel pad may be further provided at the connecting portion of the plurality of channel structures CH1 and CH2.

Referring again to FIGS. 1 and 2, the semiconductor device may include the separation pattern WLC.

The separation patterns WLCs may penetrate the substrate insulating layer 115, the gate stack structure 120 including the plurality of gate electrodes 130 and the cell insulating layer 132, and the plurality of cell region insulating layers 132a and 132b. The separation patterns WLCs may extend in the third direction (Z-direction) while being in contact with the bottom surface of the second substrate 110.

As illustrated in FIG. 1, in a plan view, the separation patterns WLCs may extend in the second direction (Y direction) and may be spaced apart from each other by a predetermined interval in the first direction (X direction) intersecting the second direction (Y direction). For example, the separation patterns WLCs may be spaced apart and parallel to each other along the first direction (X direction). The separation patterns WLCs may separate the plurality of gate electrodes 130 from each other in the first direction (X direction). The separation patterns WLCs may be provided in plurality, but the present disclosure is not limited thereto.

The plurality of channel structures CHs may be arranged between adjacent separation patterns WLCs in the first direction (X direction). For example, the channel structures CHs along the first row to the eighth row may be arranged in a zigzag pattern along the second direction (Y direction) between adjacent separation patterns WLCs in the first direction (X direction). The separation patterns WLCs may not overlap the channel structures CH in the third direction (Z direction).

The separation pattern WLC may have a shape that decreases in width toward the bottom surface of the second substrate 110, e.g., due to a high aspect ratio. The separation pattern WLC may include at least one of silicon oxide, silicon nitride, and silicon oxynitride. However, the present disclosure is not limited thereto, and in some implementations, the separation patterns WLCs include a conductive material layer and an insulating material layer surrounding the conductive material layer.

The separation structure 300 may be located on the front side of the second substrate 110. For example, the separation structure 300 may be located on the bottom surface of the second substrate 110 facing the first substrate 210. The separation structure 300 may be located between the second substrate 110 and the first substrate 210. The separation structure 300 may be in contact with the bottom surface of the second substrate 110. For example, the separation structure 300 may be in contact with a bottom surface of the common source electrode 112.

The separation structure 300 may extend in the third direction (Z direction) from the front side of the second substrate 110. The separation structure 300 may penetrate at least portions of the plurality of gate electrodes 130 and the plurality of interlayer insulating layers 132m. For example, the separation structure 300 may penetrate the substrate insulating layer 115, at least a portion of the plurality of gate electrodes 130 located on top of the gate stack structure 120, and at least a portion of the interlayer insulating layer 132m located on top of the gate stack structure 120. In one example, as illustrated in FIG. 3, the separation structure 300 may penetrate the four gate electrodes 130 and the four interlayer insulating layers 132m located on the top of the gate stack structure 120. However, the number of ground gate electrodes 130G that the separation structure 300 penetrates is not limited thereto.

The plurality of gate electrodes 130 which the separation structure 300 penetrates may be ground gate electrodes 130G. For example, the separation structure 300 may penetrate the ground gate electrode 130G located on top of the gate stack structure 120. Accordingly, the ground gate electrode 130G may be separated by the separation structure 300 into the first portion 130G_S1 and the second portion 130G_S2. Accordingly, the first portion 130G_S1 and the second portion 130G_S2 of the ground gate electrode 130G may be electrically isolated from one another.

Referring further to FIG. 3, in some implementations, the separation structure 300 penetrates at least a portion of the channel structure CH. For example, the separation structure 300 may penetrate at least portions of the blocking layer 156, the charge storage layer 154, the tunneling layer 152, and the channel layer 140. The separation structure 300 may penetrate at least a portion of the core insulating layer 142, but the present disclosure is not limited thereto. For example, the separation structure 300 may not penetrate the core insulating layer 142. Accordingly, at least a portion of the separation structure 300 may overlap the channel structure CH in the third direction (Z direction). At least a portion of the separation structure 300 may overlap the blocking layer 156, the charge storage layer 154, the tunneling layer 152, the channel layer 140, and the core insulating layer 142 in the third direction (Z direction). The lateral surface 300_S of the separation structure 300 may be in contact with the core insulating layer 142.

In some implementations, a bottom surface 300_B of the separation structure 300 is located between a bottom surface of the ground gate electrode 130G located at the lowermost portion and the top surface of the memory gate electrode 130M located at the topmost portion. For example, the bottom surface 300_B of the separation structure 300 may be located within the interlayer insulating layer 132m. The bottom surface 300_B of the separation structure 300 may be located at a lower level than the bottom surface of the ground gate electrode 130G located at the lowermost portion. For example, the bottom surface 300_B of the separation structure 300 may be located further from the bottom surface of the second substrate 110 than the bottom surface of the ground gate electrode 130G located at the lowermost portion. However, the present disclosure is not limited thereto, and for example, as illustrated in FIG. 4, the bottom surface 300_B of the separation structure 300 may be located further from the bottom surface of the second substrate 110 than the top surface of the memory gate electrode 130M located at the topmost portion. For example, the bottom surface 300_B of the separation structure 300 may be located at a lower level than the top surface of the memory gate electrode 130M located at the topmost portion. However, even in this case, the bottom surface 300_B of the separation structure 300 may be located closer to the bottom surface of the second substrate 110 than the bottom surface of the memory gate electrode 130M located at the topmost portion. As another example, the bottom surface 300_B of the separation structure 300 may be located at the same level as the bottom surface of the ground gate electrode 130G. For example, the distance between the bottom surface 300_B of the separation structure 300 and the bottom surface of the second substrate 110 may be substantially the same as the distance between the bottom surface of the ground gate electrode 130G and the bottom surface of the second substrate 110.

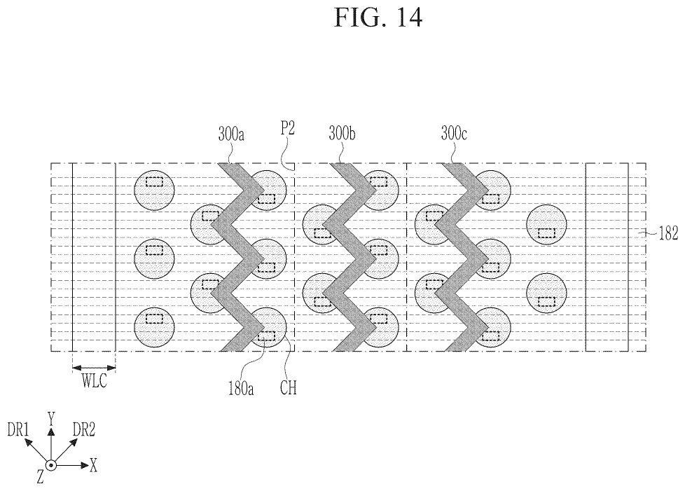

The separation structure 300 may be located between the separation patterns WLC. For example, as illustrated in FIG. 1, in a plane formed by the first direction (X direction) and the second direction (Y direction), the separation structure 300 may extend in the second direction (Y direction) between the separation patterns WLCs adjacent in the first direction (X direction). For example, the separation structure 300 may extend side by side with the separation patterns WLC. Accordingly, the separation structure 300 may separate the ground gate electrodes 130G from each other in the first direction (X direction). In FIG. 1, it is illustrated that a single separation structure 300 is provided between the separation patterns WLC adjacent in the first direction (X direction), but the present disclosure is not limited thereto. For example, the separation structures 300 may be provided in plurality and be spaced apart from each other by a predetermined interval in the first direction (X direction). These will be described below with reference to FIG. 14.

The separation structure 300 may include various insulating materials. For example, the separation structure 300 may include silicon oxide, silicon nitride, silicon oxynitride, silicon carbon oxide, silicon carbonitride, or combinations thereof, but the present disclosure is not limited thereto.

In some implementations, the separation structure 300 has a zigzag shape in a plane formed by the first direction (X direction) and the second direction (Y direction). For example, the separation structure 300 may have a zigzag shape along the second direction (Y direction) between the separation patterns WLC. In this case, as described above, the separation structure 300 may have a zigzag shape along the second direction (Y direction) to overlap with the channel structure CH.

Referring further to FIG. 5, the separation structure 300 of the semiconductor device may include a first extending portion 300_P1 extending in a first diagonal direction DR1 intersecting the first direction (X direction) and the second direction (Y direction) and a second extending portion 300_P2 extending in a second diagonal direction DR2 intersecting the first direction (X direction), the second direction (Y direction), and the first diagonal direction DR1. In some implementations, in the plane, the separation structure 300 may have the first extending portion 300_P1 and the second extending portion 300_P2 alternately located along the second direction (Y direction), defining a zigzag shape of the separation structure 300.

The first extending portion 300_P1 may extend in the first diagonal direction DR1. The first extending portion 300_P1 may extend to overlap, in the third direction (Z direction), the channel structure CH located above a first center axis CX1 extending in the second direction (Y direction), and the channel structure CH extending in the second direction (Y direction) and located above a second center axis CX2 spaced apart from the first center axis CX1 in the first direction (X direction). For example, the first extending portion 300_P1 may extend in the first diagonal direction DR1 between the first center axis CX1 and the second center axis CX2. In this case, the first center axis CX1 may mean a virtual line connecting the centers of the channel structures CH arranged along the second direction (Y direction), and the second center axis CX2 may mean a virtual line located adjacent to the first center axis CX1 in the first direction (X direction) and connecting the centers of the channel structures CHs arranged along the second direction (Y direction). The distance between the first center axis CX1 and the second center axis CX2 may be substantially the same as the distance along the first direction (X direction) between a first center CC1 of the channel structure CH located above the first center axis CX1 and a second center CC2 of the channel structure CH located above the second center axis CX2. Here, the first diagonal direction DR1 may be a direction intersecting the first direction (X direction) and the second direction (Y direction), and may refer to a direction in which the first extending portion 300_P1 extends.

Accordingly, the first extending portion 300_P1 may overlap the channel structure CH in the third direction (Z direction). For example, the first extending portion 300_P1 may overlap each of the channel structure CH located above the first center axis CX1 and the channel structure CH located above the second center axis CX2 in the third direction (Z direction). In this case, one end of the first extending portion 300_P1 may overlap the center of the channel structure CH. For example, one end of the first extending portion 300_P1 may overlap, in the third direction (Z direction), the first center CC1 of the channel structure CH located above the first center axis CX1, and the other end of the first extending portion 300_P1 may overlap, in the third direction (Z direction), the second center CC2 of the channel structure CH located above the second center axis CX2. A first length DD1 in the first diagonal direction DR1 of the first extending portion 300_P1 may be equal to or less than a second length DD2 between the first center CC1 of the channel structure CH located above the first center axis CX1 and the second center CC2 of the channel structure CH located above the second center axis CX2.

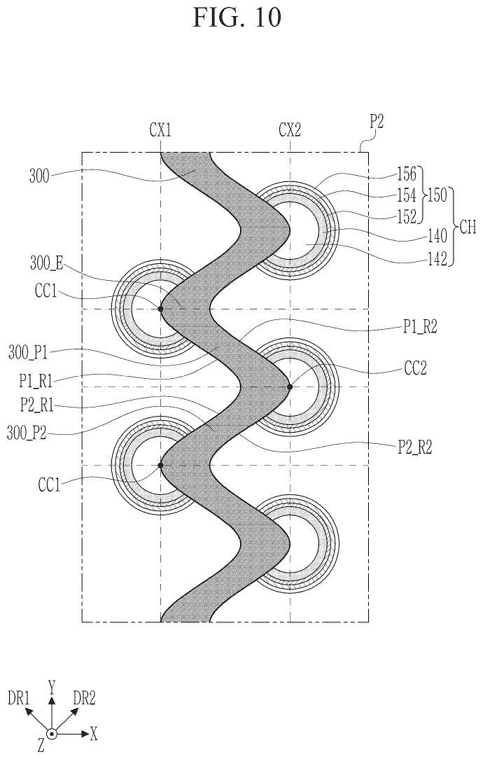

The first extending portion 300_P1 may include a first lateral surface P1_S1 facing the first portion 130G_S1 of the ground gate electrode 130G, and a second lateral surface P1_S2 facing the second portion 130G_S2 of the ground gate electrode 130G. The first lateral surface P1_S1 of the first extending portion 300_P1 may be opposite the second lateral surface P1_S2 of the first extending portion 300_P1. The first lateral surface P1_S1 of the first extending portion 300_P1 and the second lateral surface P1_S2 of the first extending portion 300_P1 may extend straight. For example, the first lateral surface P1_S1 of the first extending portion 300_P1 and the second lateral surface P1_S2 of the first extending portion 300_P1 may be flat. Accordingly, the first lateral surface P1_S1 of the first extending portion 300_P1 and the second lateral surface P1_S2 of the first extending portion 300_P1 may extend side by side (e.g., parallel to one another) in the first diagonal direction DR1. However, the present disclosure is not limited thereto, and the first lateral surface P1_S1 and the second lateral surface P1_S2 of the first extending portion 300_P1 may have a curved surface, e.g., as described with respect to FIG. 10.

The first lateral surface P1_S1 of the first extending portion 300_P1 may be in contact with the channel structure CH located above the first center axis CX1. For example, the first lateral surface P1_S1 of the first extending portion 300_P1 may be in contact with the blocking layer 156, the charge storage layer 154, the tunneling layer 152, the channel layer 140, and the core insulating layer 142 of the channel structure CH located above the first center axis CX1. The first lateral surface P1_S1 of the first extending portion 300_P1 may be in contact with the first portion 130G_S1 of the ground gate electrode 130G. The second lateral surface P1_S2 of the first extending portion 300_P1 may be in contact with the channel structure CH located above the second center axis CX2. For example, the second lateral surface P1_S2 of the first extending portion 300_P1 may be in contact with the blocking layer 156, the charge storage layer 154, the tunneling layer 152, the channel layer 140, and the core insulating layer 142 of the channel structure CH located above the second center axis CX2. The second lateral surface P1_S2 of the first extending portion 300_P1 may be in contact with the second portion 130G_S2 of the ground gate electrode 130G.

A first width T1 of the first extending portion 300_P1 may be equal to or less than a radius of the channel structure CH. Here, the first width T1 of the first extending portion 300_P1 may refer to a minimum distance between the first lateral surface P1_S1 and the second lateral surface P1_S2 of the first extending portion 300_P1. However, the present disclosure is not limited thereto, and the first width T1 of the first extending portion 300_P1 may be greater than the radius of the channel structure CH.

The second extending portion 300_P2 may extend in the second diagonal direction DR2. The second extending portion 300_P2 may extend to overlap, in the third direction (Z direction), the channel structure CH located above the first center axis CX1 extending in the second direction (Y direction), and the channel structure CH extending in the second direction (Y direction) and located above the second center axis CX2 spaced apart from the first center axis CX1 in the first direction (X direction). For example, the second extending portion 300_P2 may extend in the second diagonal direction DR2 between the first center axis CX1 and the second center axis CX2. Here, the second diagonal direction DR2 may be a direction intersecting the first direction (X direction), the second direction (Y direction), and the first diagonal direction DR1, and may refer to a direction in which the second extending portion 300_P2 extends.

Accordingly, the second extending portion 300_P2 may overlap the channel structure CH in the third direction (Z direction). For example, the second extending portion 300_P2 may overlap each of the channel structure CH located above the first center axis CX1 and the channel structure CH located above the second center axis CX2 in the third direction (Z direction). One end of the second extending portion 300_P2 may overlap the center of the channel structure CH. For example, one end of the second extending portion 300_P2 may overlap, in the third direction (Z direction), the first center CC1 of the channel structure CH located above the second center axis CX2, and the other end of the second extending portion 300_P2 may overlap, in the third direction (Z direction), the second center CC2 of the channel structure CH located above the first center axis CX1.

A fourth length DD4 along the second direction (Y direction) of the second extending portion 300_P2 may be substantially the same as a third length DD3 along the second direction (Y direction) of the first extending portion 300_P1. However, the present disclosure is not limited thereto, and the fourth length DD4 along the second direction (Y direction) of the second extending portion 300_P2 may be longer or shorter than the third length DD3 along the second direction (Y direction) of the first extending portion 300_P1.

The second extending portion 300_P2 may include a first lateral surface P2_S1 facing the first portion 130G_S1 of the ground gate electrode 130G, and a second lateral surface P2_S2 facing the second portion 130G_S2 of the ground gate electrode 130G. The first lateral surface P2_S1 of the second extending portion 300_P2 may be opposite the second lateral surface P2_S2 of the second extending portion 300_P2. The first lateral surface P2_S1 of the second extending portion 300_P2 and the second lateral surface P2_S2 of the second extending portion 300_P2 may extend straight (e.g., parallel to one another). For example, the first lateral surface P2_S1 of the second extending portion 300_P2 and the second lateral surface P2_S2 of the second extending portion 300_P2 may be flat. Accordingly, the first lateral surface P2_S1 of the second extending portion 300_P2 and the second lateral surface P2_S2 of the second extending portion 300_P2 may extend side by side in the second diagonal direction DR2. However, the present disclosure is not limited thereto, and the first lateral surface P2_S1 and the second lateral surface P2_S2 of the second extending portion 300_P2 may have a curved surface, e.g., as described with respect to FIG. 10.

The first lateral surface P2_S1 of the second extending portion 300_P2 may be in contact with the channel structure CH located above the first center axis CX1. For example, the first lateral surface P2_S1 of the second extending portion 300_P2 may be in contact with the blocking layer 156, the charge storage layer 154, the tunneling layer 152, the channel layer 140, and the core insulating layer 142 of the channel structure CH located above the first center axis CX1. The first lateral surface P2_S1 of the second extending portion 300_P2 may be in contact with the first portion 130G_S1 of the ground gate electrode 130G. The second lateral surface P2_S2 of the second extending portion 300_P2 may be in contact with the channel structure CH located above the second center axis CX2. For example, the second lateral surface P2_S2 of the second extending portion 300_P2 may be in contact with the blocking layer 156, the charge storage layer 154, the tunneling layer 152, the channel layer 140, and the core insulating layer 142 of the channel structure CH located above the second center axis CX2. The second lateral surface P2_S2 of the second extending portion 300_P2 may be in contact with the second portion 130G_S2 of the ground gate electrode 130G.

The width of the second extending portion 300_P2 may be substantially the same as the first width T1 of the first extending portion 300_P1. The width of the second extending portion 300_P2 may be equal to or less than the radius of the channel structure CH. Here, the width of the second extending portion 300_P2 may refer to a minimum distance between the first lateral surface P2_S1 and the second lateral surface P2_S2 of the second extending portion 300_P2. However, the present disclosure is not limited thereto, and the width of the second extending portion 300_P2 may be greater than the radius of the channel structure CH.

A first angle 01 between the first lateral surface P2_S1 of the second extending portion 300_P2 and the first lateral surface P1_S1 of the first extending portion 300_P1 may be equal to or greater than 30° and less than 180°. This angular range may allow the separation structure 300 to have a zigzag shape and overlap the channel structure CH in the third direction (Z direction).

The separation structure 300 of the semiconductor device may further include a bent portion 300_E located between the first extending portion 300_P1 and the second extending portion 300_P2.

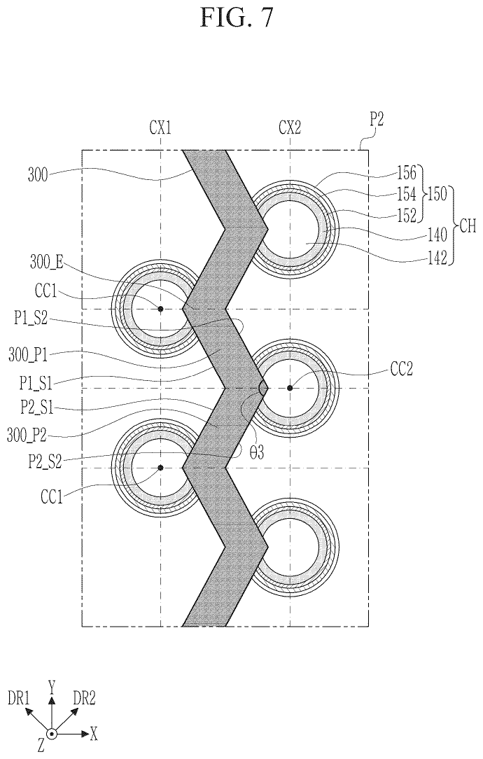

The bent portion 300_E may include a point where the first extending portion 300_P1 and the second extending portion 300_P2 meet. For example, the bent portion 300_E may include a point where the extension direction of the separation structure 300 changes. For example, the bent portion 300_E may include a point where the extension direction of the separation structure 300 changes from the first diagonal direction DR1 to the second diagonal direction DR2 and a point where the extension direction of the separation structure 300 changes from the second diagonal direction DR2 to the first diagonal direction DR1. In this case, as illustrated in FIG. 5, the point where the extension direction of the separation structure 300 changes from the first diagonal direction DR1 to the second diagonal direction DR2 may overlap the first center CC1 of the channel structure CH located above the first center axis CX1 in the third direction (Z direction). Furthermore, the point where the extension direction of the separation structure 300 changes from the second diagonal direction DR2 to the first diagonal direction DR1 may overlap the second center CC2 of the channel structure CH located above the second center axis CX2 in the third direction (Z direction). Accordingly, the bent portion 300_E may overlap the first center CC1 of the channel structure CH located above the first center axis CX1 in the third direction (Z direction). Further, the bent portion 300_E may overlap the second center CC2 of the channel structure CH located above the second center axis CX2 in the third direction (Z direction). However, the present disclosure is not limited thereto, and the bent portion 300_E may not overlap, in the third direction (Z direction), the first center CC1 of the channel structure CH located above the first center axis CX1 and/or the second center CC2 of the channel structure CH located above the second center axis CX2. An example of such an arrangement is described with reference to FIG. 7.

Furthermore, FIG. 5 illustrates that an edge of the bent portion 300_E is in contact with the first center CC1 of the channel structure CH located above the first center axis CX1 and the second center CC2 of the channel structure CH located above the second center axis CX2, but the present disclosure is not limited thereto. For example, an edge of the bent portion 300_E may be located in an outward direction with respect to the first center axis CX1 and in an outward direction with respect to the second center axis CX2. Here, the outward direction of the first center axis CX1 may mean the opposite direction of the direction from the first center axis CX1 toward the second center axis CX2. Also, the outward direction of the second center axis CX2 may mean the opposite direction of the direction from the second center axis CX2 toward the first center axis CX1. For example, the point where the first extending portion 300_P1 and the second extending portion 300_P2 meet may be located in the outward direction of the first center axis CX1 and the outward direction of the second center axis CX2.

In some implementations, the bent portion 300_E overlaps the channel structure CH in the third direction (Z direction). For example, the bent portion 300_E may overlap the blocking layer 156, the charge storage layer 154, the tunneling layer 152, the channel layer 140, and the core insulating layer 142 in the third direction (Z direction). The lateral surface of the bent portion 300_E may be in contact with the blocking layer 156, the charge storage layer 154, the tunneling layer 152, the channel layer 140, and the core insulating layer 142. For example, the channel structure CH located on the first center axis CX1 may be in contact with the first lateral surface P1_S1 of the first extending portion 300_P1 and the first lateral surface P2_S1 of the second extending portion 300_P2. An inner surface of the channel structure CH may be defined by the first lateral surface P1_S1 of the first extending portion 300_P1 and the first lateral surface P2_S1 of the second extending portion 300_P2. Thus, the channel structure CH may have an inner surface extending in the first diagonal direction DR1 and the second diagonal direction DR2 at a predetermined angle. Accordingly, the channel layer 140 of the channel structure CH may be surrounded along the circumferential direction of the channel structure CH by the ground gate electrode 130G.

The ground gate electrode 130G of the semiconductor device may be separated in the first direction (X direction) by the separation structure 300. In this case, the separation structure 300 has a zigzag shape along the second direction (Y direction) such that the separation structure 300 overlaps the channel structure CH in the third direction (Z direction), so that a margin overlapping the channel structure CH in the third direction (Z direction) may be secured in the process of forming the separation structure 300.

Moreover, the channel layer 140 of the channel structure CH may be surrounded by the ground gate electrode 130G. In this case, the bent portion 300_E of the separation structure 300 may penetrate at least a portion of the channel structure CH, so that the channel structure CH may have an inner surface extending in the first diagonal direction DR1 and the second diagonal direction DR2 at a predetermined angle. Accordingly, the channel layer 140 of the channel structure CH may be surrounded along the circumferential direction of the channel structure CH by the ground gate electrode 130G. Accordingly, the angle (or area) at or by which the channel layer 140 is surrounded by the ground gate electrode 130G may be increased, and the reliability of the semiconductor device may be improved.

The semiconductor device may further include a select separation pattern SLC, as shown in FIG. 2.

The select separation pattern SLC may penetrate at least some of the plurality of gate electrodes 130. For example, the select separation pattern SLC may penetrate the select gate electrode 130S located at a lower portion of the plurality of gate electrodes 130, but the present disclosure is not limited thereto.

The select separation pattern SLC may have a zigzag shape in a plane formed by the first direction (X direction) and the second direction (Y direction) or a line shape extending in the second direction (Y direction), but the present disclosure is not limited thereto. The select separation pattern SLC may extend approximately side by side with the separation structure 300 and the separation pattern WLC. In this case, a top surface of the select separation pattern SLC may be located at a higher level than the top surface of the select gate electrode 130S, but the present disclosure is not limited thereto. The bottom surface of the select separation pattern SLC may be located at a lower level than the bottom surface of the gate stack structure 120.

In FIG. 2, only one select separation pattern SLC is illustrated between the separation patterns WLCs adjacent in the first direction (X direction), but the present disclosure is not limited to. For example, a plurality of select separation patterns WLCs may be located between the separation patterns WLCs adjacent in the first direction (X direction). In this case, the interval between the separation patterns WLCs adjacent in the first direction (X direction) may be greater than the interval between the select separation patterns SLCs adjacent in the first direction (X direction). In other words, in a plane, at least some of the select separation patterns SLCs may be located between the separation patterns WLCs adjacent in the first direction (X direction). The select separation pattern SLC may include an insulating material, such as silicon oxide. However, the present disclosure is not limited thereto.

The semiconductor device may further include an upper wiring structure.

The upper wiring structure may be electrically connected to the channel structure CH. The upper wiring structure may include any member that electrically connects the gate electrode 130, the channel structure CH, and the like with a peripheral circuit area PERI or external circuits. For example, the upper wiring structure may include bit lines 182 and contact vias 180a. The bit line 182 may be located on a bottom surface of the cell insulating layer 132 of the gate stack structure 120. The bit line 182 may extend in a direction that intersects with a direction in which the gate electrodes 130 extend. The bit line 182 may be electrically connected to the channel structure CH (for example, channel pad 144) via contact vias 180a.

As shown in FIG. 2, one surface of the cell structure CELL adjacent to the peripheral circuit structure PERI is a junction surface with the peripheral circuit structure PERI, and may be formed of a second junction structure 190 and a portion of the second inter-wiring insulating layer 192 located around the second junction structure 190. The second junction structure 190 may be electrically connected to the bit line 182.

One surface of the cell structure CELL and one surface of the peripheral circuit structure PERI may be bonded by hybrid joining. For example, the first junction structure 290 of the peripheral circuit structure PERI and the second junction structure 190 of the cell structure CELL may be bonded in a direct contact state to form a metal junction. Further, a portion of the first inter-wiring insulating layer 232 of the peripheral circuit structure PERI and a portion of the second inter-wiring insulating layer 192 of the cell structure CELL may be bonded to one another. However, the present disclosure is not limited thereto, and, for example, a separate junction insulating layer may be provided between the first inter-wiring insulating layer 232 and the second inter-wiring insulating layer 192, and portions of the junction insulating layers may be bonded to each other.

The second junction structure 190 may be made of copper, aluminum, tungsten, nickel, gold, tin, manganese, cobalt, titanium, tantalum, ruthenium, or an alloy thereof. In some implementations, the second junction structure 190 includes copper at least at the junction surface, such that the metal junction of the peripheral circuit structure PERI and the cell structure CELL may be configured as a copper-to-copper junction. However, materials of the second junction structure 190 are not limited thereto.

As such, the first junction structure 290 of the peripheral circuit structure PERI and the second junction structure 190 of the cell structure CELL may be bonded to provide an electrical connection path between the peripheral circuit structure PERI and the cell structure CELL. For example, the bit line 182 and/or gate electrode 130 connected to the channel structure CH via the first and second contact vias 236 and 234 may be electrically connected to the circuit element 220 of the peripheral circuit structure PERI.

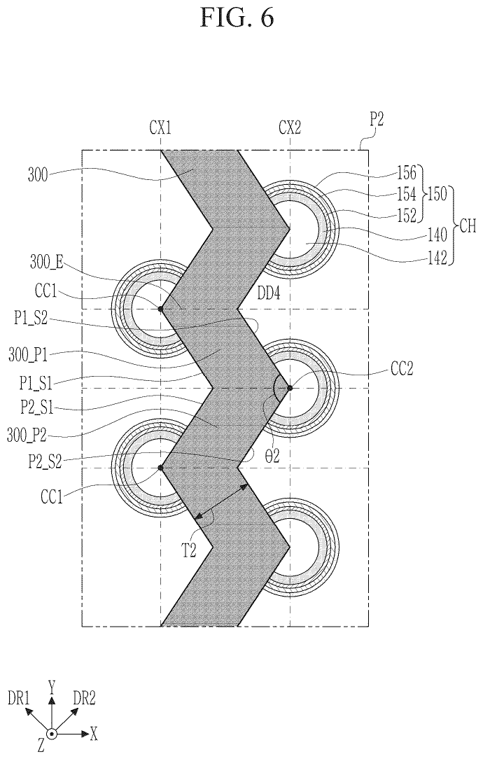

Hereinafter, a semiconductor device according to some implementations will be described with reference to FIGS. 6 to 13.

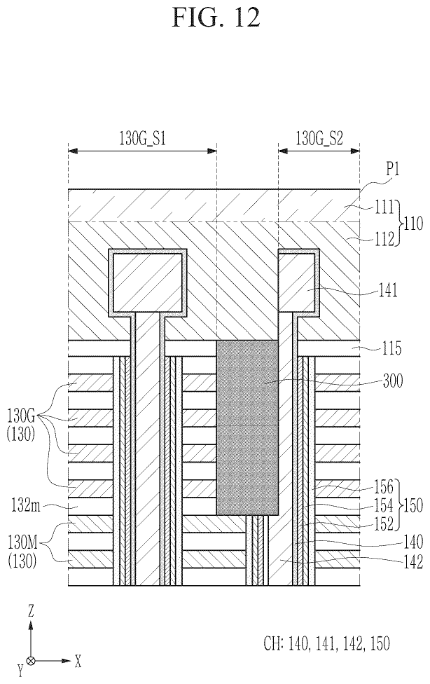

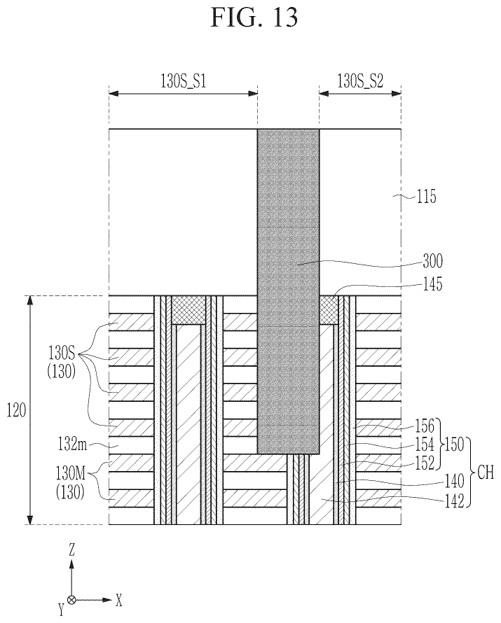

FIGS. 6 to 11 are cross-sectional views corresponding to region P2 of FIG. 1. FIGS. 12 and 13 are cross-sectional views corresponding to region P1 of FIG. 2.

Since the examples illustrated in FIGS. 6 to 13 have substantially the same in some elements as those of FIGS. 1 to 5, a description of the same characteristics will be omitted. The description provided with respect to FIGS. 1 to 5 can be applied equally to FIGS. 6 to 13, except where noted otherwise or suggested otherwise by context.

As discussed above, a cell structure CELL may include a second substrate 110, a gate stack structure 120 located on a bottom surface of the second substrate 110, a channel structure CH penetrating the gate stack structure 120, and a separation structure 300 penetrating at least a portion of the gate stack structure 120. Here, the gate stack structure 120 may include a plurality of alternately stacked gate electrodes 130 and a cell insulating layer 132.

Referring to FIG. 6, a width of the separation structure 300 of the semiconductor device may be larger than a radius of the channel structure CH. For example, a second width T2 of a first extending portion 300_P1 may be larger than the radius of the channel structure CH. Further, a width of the second extending portion 300_P2 may be substantially the same as the second width T2 of the first extending portion 300_P1. That is, the width of the second extending portion 300_P2 may be equal to or less than the radius of the channel structure CH. Here, the second width T2 of the first extending portion 300_P1 may refer to a minimum distance between a first lateral surface P1_S1 and a second lateral surface P1_S2 of the first extending portion 300_P1. Here, the width of the second extending portion 300_P2 may refer to a minimum distance between the first lateral surface P2_S1 and the second lateral surface P2_S2 of the second extending portion 300_P2.

Further, in some implementations, a second angle 02 between the first lateral surface P2_S1 of the second extending portion 300_P2 and the first lateral surface P1_S1 of the first extending portion 300_P1 is equal to or greater than 90° and less than 180°. For angles in this range, the separation structure 300 may have a zigzag shape and overlap the channel structure CH in the third direction (Z direction).

Referring to FIG. 7, the separation structure 300 of the semiconductor device may not overlap, in the third direction (Z direction), a first center CC1 of the channel structure CH located above a first center axis CX1 and a second center CC2 of the channel structure CH located above a second center axis CX2. For example, the separation structure 300 may be spaced apart from the first center CC1 and the second center CC2 laterally in the first and/or second directions X and/or Y.

For example, a bent portion 300_E of the separation structure 300 may not overlap, in the third direction (Z direction), the first center CC1 of the channel structure CH located above the first center axis CX1 and the second center CC2 of the channel structure CH located above the second center axis CX2. For example, the point where the first extending portion 300_P1 and the second extending portion 300_P2 meet may be located closer to the second center axis CX2 than the first center CC1 of the channel structure CH, which is located above the first center axis CX1. The point where the first extending portion 300_P1 and the second extending portion 300_P2 meet may be located closer to the first center axis CX1 than the second center CC2 of the channel structure CH, which is located above the second center axis CX2.

In at least the example of FIG. 7, the first extending portion 300_P1 and the second extending portion 300_P2 may penetrate at least a portion of the channel structure CH. For example, the first extending portion 300_P1 and the second extending portion 300_P2 may overlap at least a portion of the channel structure CH in the third direction (Z direction). For example, the first extending portion 300_P1 and the second extending portion 300_P2 may extend to overlap, in the third direction (Z direction), the channel structure CH located above the first center axis CX1 and the channel structure CH located above the second center axis CX2. For example, the first extending portion 300_P1 and the second extending portion 300_P2 may overlap, in the third direction (Z direction), the blocking layer 156, the charge storage layer 154, the tunneling layer 152, the channel layer 140, and the core insulating layer 142 of the channel structure CH. The first extending portion 300_P1 and the second extending portion 300_P2 may be in contact with the blocking layer 156, the charge storage layer 154, the tunneling layer 152, the channel layer 140, and the core insulating layer 142 of the channel structure CH.

In some implementations, a third angle θ3 between the first lateral surface P2_S1 of the second extending portion 300_P2 and the first lateral surface P1_S1 of the first extending portion 300_P1 is equal to or greater than the first angle θ1 between the first lateral surface P2_S1 of the second extending portion 300_P2 and the first lateral surface P1_S1 of the first extending portion 300_P1 of the example of FIG. 1.

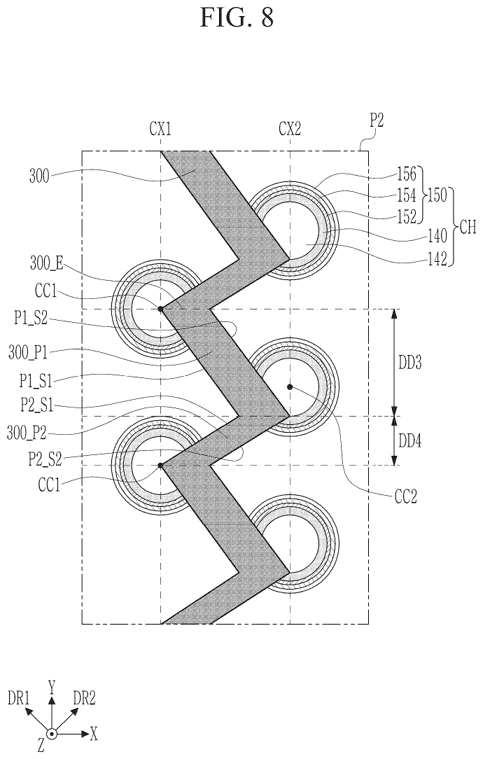

Referring to FIG. 8, in some implementations, a fourth length DD4 along the second direction (Y direction) of the second extending portion 300_P2 of the separation structure 300 is different from the third length DD3 along the second direction (Y direction) of the first extending portion 300_P1. For example, the fourth length DD4 along the second direction (Y direction) of the second extending portion 300_P2 may be smaller than the third length DD3 along the second direction (Y direction) of the first extending portion 300_P1. Accordingly, the area in which the separation structure 300 overlaps, in the third direction (Z direction), the channel structure CH located above the first center axis CX1 may be larger than the area in which the separation structure 300 overlaps, in the third direction (Z direction), the channel structure CH located above the second center axis CX2, but the present disclosure is not limited thereto.

The present disclosure is not limited to the foregoing lengths DD3 and DD4, and, for example, the fourth length DD4 along the second direction (Y direction) of the second extending portion 300_P2 may be larger than the third length DD3 along the second direction (Y direction) of the first extending portion 300_P1.

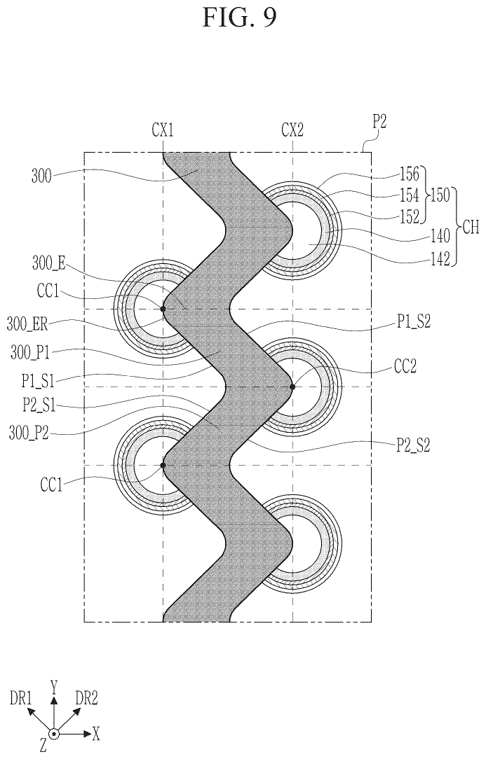

Referring to FIGS. 9 and 10, in some implementations, the separation structure 300 of the semiconductor device includes a curved surface. For example, as illustrated in FIG. 9, a lateral surface 300_ER of the bent portion 300_E of the separation structure 300 may include a curved surface. The lateral surface 300_ER of the bent portion 300_E may have a convex shape toward the center of the channel structure CH. For example, the point where the first extending portion 300_P1 and the second extending portion 300_P2 of the separation structure 300 meet may include a curved surface. The first extending portion 300_P01 and the second extending portion 300_P2 may have straight lateral surfaces.

As another example, as illustrated in FIG. 10, the lateral surfaces of the first extending portion 300_P1 and the second extending portion 300_P2 of the separation structure 300 may include curved surfaces. For example, the lateral surface of the first extending portion 300_P1 may include a first curved surface P1_R1 facing a first portion 130G_S1 of the ground gate electrode 130G and a second curved surface P1_R2 facing a second portion 130G_S2 of the ground gate electrode 130G. In this case, the curvature of the first curved surface P1_R1 of the first extending portion 300_P1 and the curvature of the second curved surface P1_R2 may be substantially the same, but the present disclosure is not limited thereto. Further, the lateral surface of the second extending portion 300_P2 may include a first curved surface P2_R1 facing the first portion 130G_S1 of the ground gate electrode 130G and a second curved surface P2_R2 facing the second portion 130G_S2 of the ground gate electrode 130G. In this case, the curvature of the first curved surface P2_R1 of the second extending portion 300_P2 and the curvature of the second curved surface P2_R2 may be substantially the same, but the curvatures are not limited thereto. Further, the curvature of the first curved surface P1_R1 of the first extending portion 300_P1 and the curvature of the first curved surface P2_R1 of the second extending portion 300_P2 may be substantially the same, but the curvatures are not limited thereto.

However, the present disclosure is not limited thereto, and at least a portion of the lateral surface of the separation structure 300 may include a curved surface, while other portions may include flat surfaces.

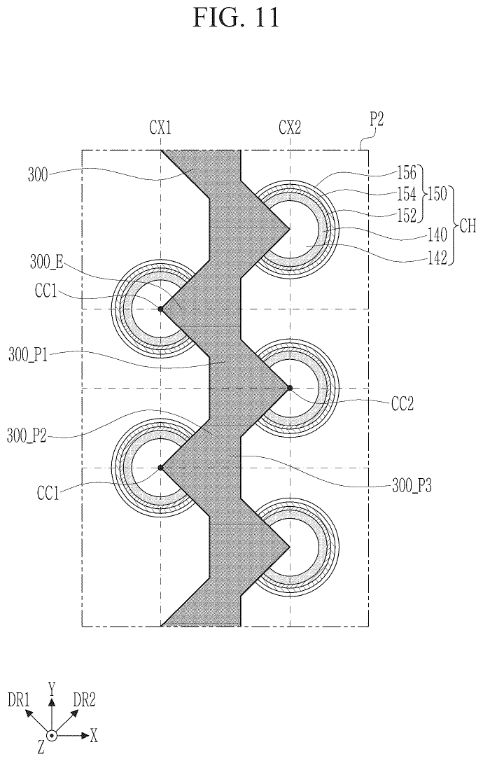

Referring to FIG. 11, the separation structure 300 of the semiconductor device according to some implementations may include a third extending portion 300_P3 located between the first extending portion 300_P1 and the second extending portion 300_P2. The third extending portion 300_P3 may extend in the second direction (Y direction). For example, the third extending portion 300_P3 may extend in the second direction (Y direction) between the first extending portion 300_P1 and the second extending portion 300_P2. The third extending portion 300_P3 may be integrally formed with the first extending portion 300_P1 and the second extending portion 300_P2. It is illustrated that the lateral surface of the third extending portion 300_P3 is a flat surface, but the present disclosure is not limited thereto. For example, the lateral surface of the third extending portion 300_P3 may include a sloped surface having a plurality of slopes. In some implementations, the lateral surface of the third extending portion 300_P3 may include a curved surface.

The separation structures 300 of each of FIGS. 5 to 11 have a zigzag shape.

FIGS. 12 and 13 illustrate examples of the channel structure CH and the separation structure 300. Except where noted otherwise or suggested otherwise by context, the elements of FIGS. 12 and 13 can have the characteristics described with respect to FIGS. 1 to 5.

Referring to FIG. 12, the channel structure CH of the semiconductor device may include a stopper pattern 141.

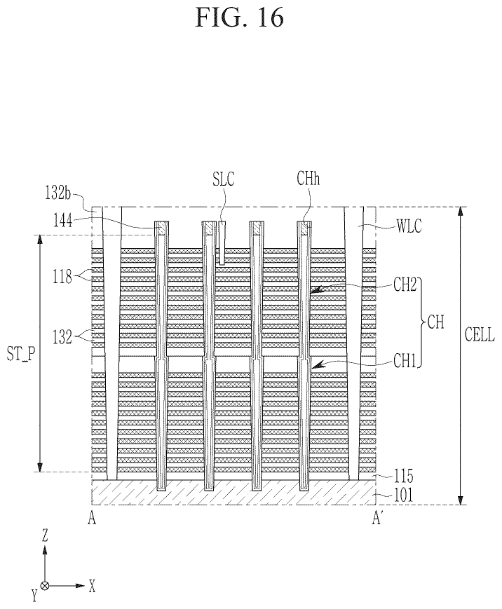

The stopper pattern 141 may be embedded within the second substrate 110. For example, the stopper pattern 141 may be embedded within the common source electrode 112. A width along a horizontal direction (for example, the first direction (X direction) and/or the second direction (Y direction)) of the stopper pattern 141 may be greater than a width along a horizontal direction (for example, the first direction (X direction) and/or the second direction (Y direction) of the core insulating layer 142, but the present disclosure is not limited thereto. The stopper pattern 141 may overlap the core insulating layer 142 in the third direction (Z direction). At least a portion of a bottom surface of the stopper pattern 141 may be in contact with the core insulating layer 142. The stopper pattern 141 may function as a stopper to prevent the second substrate 110 from being penetrated in the process of forming a channel hole (CHh in FIG. 16) penetrating the gate stack structure 120 and penetrating at least a portion of the second substrate 110.

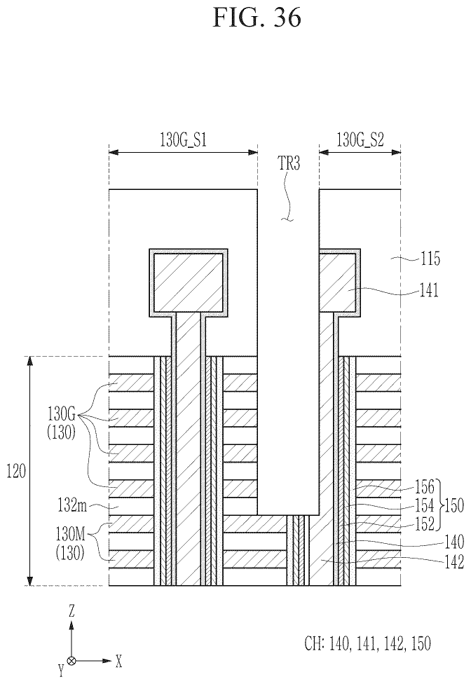

In some implementations, the stopper pattern 141 may be in contact with the common source electrode 112. For example, a lateral surface of the stopper pattern 141 may be in contact with the common source electrode 112. This may be caused due to the characteristic of a fabricatoin process, in which at least a portion of the stopper pattern 141 is removed together in the process of forming a third trench (TR3 in FIG. 36) penetrating the second substrate 110.

In some implementations, the channel layer 140 surrounds the stopper pattern 141. For example, the channel layer 140 may surround at least a portion of the top surface, a lateral surface, and a bottom surface of the stopper pattern 141.

Referring to FIG. 13, in some implementations, a select gate electrode 130S is located on top of the gate stack structure 120. For example, the select gate electrode 130S may be located adjacent to a bottom surface of the substrate insulating layer 115. Further, the semiconductor device may not include the second substrate 110.

In some implementations, portions of at least some of the select gate electrodes 130S are spaced apart from one another. For example, as illustrated in FIG. 13, the select gate electrodes 130S may be separated into a first portion 130S_S1 and a second portion 130S_S2 by the separation structure 300. Accordingly, the first portion 130S_S1 of the select gate electrode 130S and the second portion 130S_S2 of the select gate electrode 130S may be spaced apart in the first direction (X direction). The first portion 130S_S1 of the select gate electrode 130S may not be electrically connected with the second portion 130S_S2 of the select gate electrode 130S. Further, the select gate electrodes 130S may be separated in the first direction (X direction) by the separation patterns WLC, but the present disclosure is not limited thereto.

The separation structure 300 of the semiconductor device may penetrate at least a portion of the substrate insulating layer 115 and the select gate electrode 130S to separate the select gate electrode 130S in the first direction (X direction). The separation structure 300 may have a zigzag shape in a plane formed of the first direction (X direction) and the second direction (Y direction), and also penetrate at least a portion of the channel structure CH.

In some implementations, as shown in FIG. 13, the channel structure CH further includes an upper channel pad 145. The upper channel pad 145 may be located on top of the channel structure CH and may be electrically connected to the channel layer 140. The upper channel pad 145 may be electrically connected to circuit wires via contact vias and/or the like. For example, the circuit wires and the channel layer 140 may be electrically connected via the upper channel pad 145. At least a portion of the upper channel pad 145 may be penetrated by the separation structure 300. For example, the separation structure 300 may penetrate at least portions of the upper channel pad 145, the blocking layer 156, the charge storage layer 154, the tunneling layer 152, the channel layer 140, and the core insulating layer 142.

In FIG. 13, it is illustrated that four select gate electrodes 130S are located at the topmost portion of the gate stack structure 120, but the present disclosure is not limited thereto. For example, three or fewer select gate electrodes 130S may be located at the topmost portion of the gate stack structure 120. Alternatively, five or more select gate electrodes 130S may be located at the topmost portion of the gate stack structure 120. As another example, at least some of the select gate electrodes 130S may be configured as gate electrodes that form erase transistors utilized for an erase operation utilizing a gate induced drain leakage (GIDL) phenomenon. At least some of the plurality of gate electrodes 130 (for example, memory gate electrodes 130M adjacent to the select gate electrodes 130S) may be dummy gate electrodes.

FIG. 14 is a top plan view illustrating a semiconductor device according to some implementations of the present disclosure.

Referring to FIG. 14, the separation structures 300 of the semiconductor device may be located between the separation patterns WLC. In this case, in the plane formed of the first direction (X direction) and the second direction (Y direction), the separation structures 300a to 300c are provided in plural. Each of the separation structures 300a to 300c may extend in the second direction (Y direction) between separation patterns WLC adjacent in the first direction (X direction). Each of the separation structures 300a to 300c may be spaced apart from each other in the first direction (X direction) by a predetermined interval. For example, the separation structures 300a to 300c may include first to third separation structure 300a, 300b, and 300c between the separation patterns WLCs adjacent in the first direction (X direction).

In some implementations, the first to third separation structures 300a, 300b, and 300c have the same shape as each other, but the present disclosure is not limited thereto. The first to third separation structures 300a, 300b, and 300c may have a zigzag shape in the plane formed of the first direction (X direction) and the second direction (Y direction). The separation structure 300 may overlap the channel structure CH.

In some implementations, the separation structures 300a to 300c separate the ground gate electrodes 130G from each other in the first direction (X direction). For example, the ground gate electrodes 130G may be separated from each other between the separation pattern WLC and the first separation structure 300a, between the first separation structure 300a and the second separation structure 300b, between the second separation structure 300b and the third separation structure 300c, and between the third separation structure 300c and the separation pattern WLC. The separation pattern WLC and the first separation structure 300a, the first separation structure 300a and the second separation structure 300b, the second separation structure 300b and the third separation structure 300c, and the third separation structure 300c and the separation pattern WLC may have substantially the same intervals therebetween, but the present disclosure is not limited thereto. An equal number of channel structures CH may be located between the separation pattern WLC and the first separation structure 300a, between the first separation structure 300a and the second separation structure 300b, between the second separation structure 300b and the third separation structure 300c, and between the third separation structure 300c and the separation pattern WLC. For example, two channel structures CHs arranged in a direction similar to the first diagonal direction DR1 may be located between each of the separation structures 300a to 300c, as illustrated in the example of FIG. 14, but the present disclosure is not limited thereto.

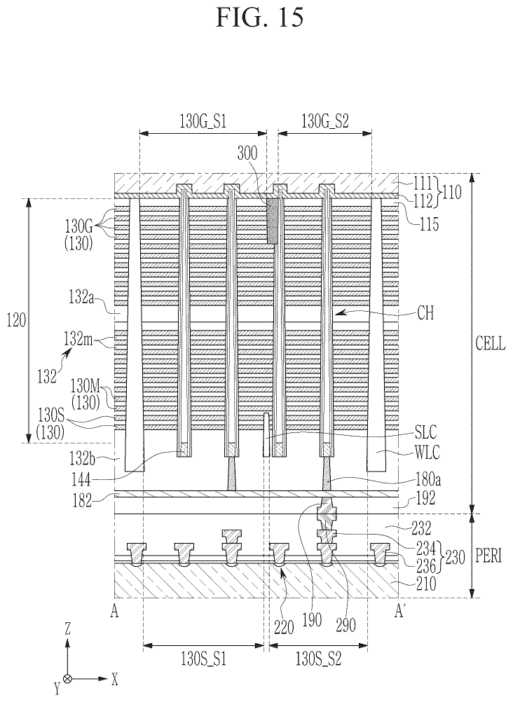

Hereinafter, another example of a semiconductor device will be described with reference to FIG. 15. Aspects of the device that are identical to those of the previously described examples of FIGS. 1 to 14 will be indicated by the same reference numerals, and redundant descriptions will be omitted or simplified; differences will be mainly described.

Referring to FIG. 15, a channel structure CH of a semiconductor device according to some implementations may not include a bent portion. Accordingly, the channel structure CH may have a sloping lateral surface such that, when viewed in cross-section, the width narrows as it approaches a second substrate 110, depending on the aspect ratio.

In FIG. 15, it is illustrated that a gate stack structure 120 includes a plurality of cell region insulating layers 132a and 132b, but the present disclosure is not limited thereto. For example, the gate stack structure 120 may include a second cell region insulating layer 132b located between a gate electrode 130 located at the lowermost portion and the first substrate 210, and may not include a first cell region insulating layer 132a.

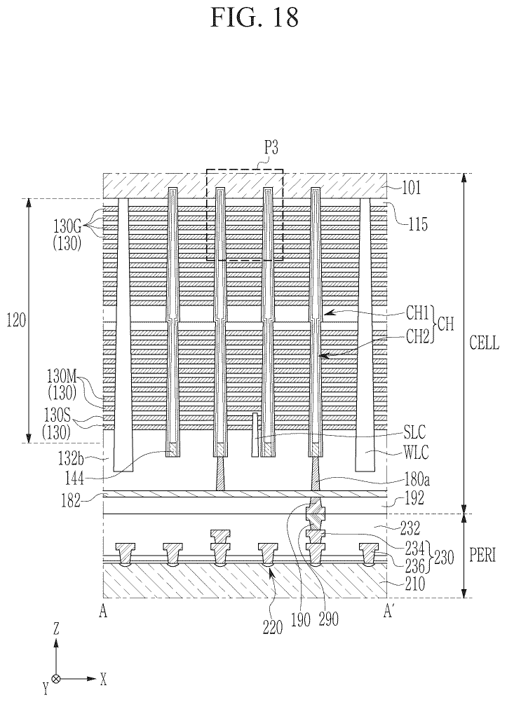

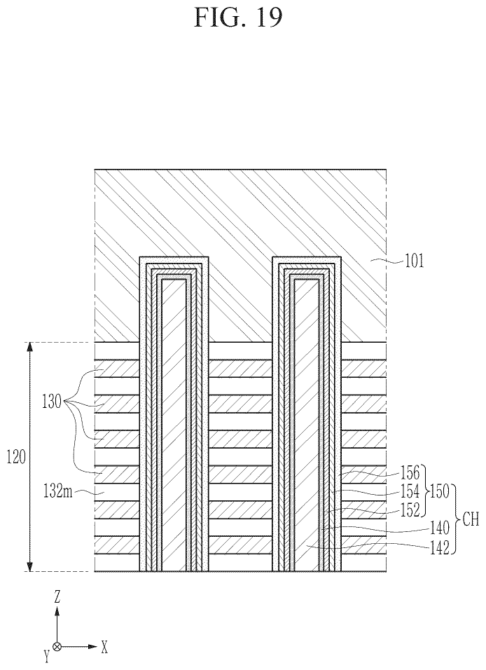

FIGS. 16 to 18 are cross-sectional views illustrating intermediate operations of a method of manufacturing a semiconductor device. FIGS. 19 to 26 are cross-sectional views corresponding to region P3 of FIG. 18, illustrating intermediate operations in the method of manufacturing the semiconductor device. In the following, the same configurations described previously are referred with the same references, redundant descriptions will be omitted or simplified, and the differences will be mainly described. The manufactured device can have characteristics as described with respect to FIGS. 1 to 15.

Referring to FIG. 16, a preliminary stack structure ST_P may be formed on a sacrificial substrate 101, and a channel structure CH may be formed.

First, a substrate insulating layer 115 may be formed on the sacrificial substrate 101, and a preliminary stack structure ST_P may be formed by alternately stacking sacrificial insulating layers 118 and cell insulating layers 132 on the substrate insulating layer 115.

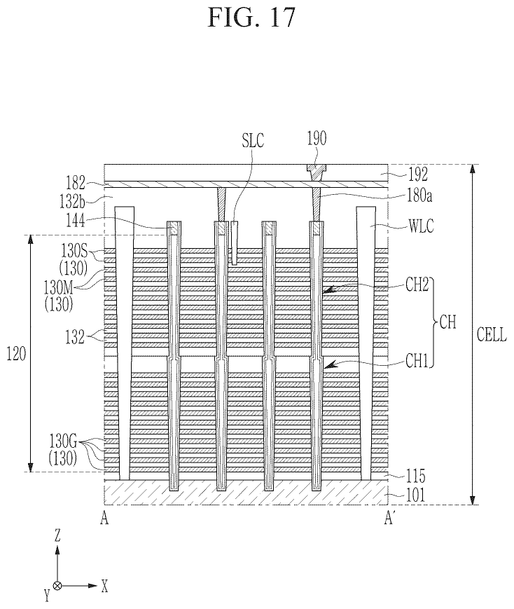

The sacrificial insulating layers 118 may be layers that are partially replaced with gate electrodes (see reference numeral “130” in FIG. 17) through a subsequent process. The sacrificial insulating layer 118 may be made of a different material from that of the cell insulating layer 132. The sacrificial insulating layer 118 may include a material having an etch selectivity ratio with respect to the cell insulating layer 132. For example, the cell insulating layer 132 may be made of at least one of silicon oxide and silicon nitride, and the sacrificial insulating layer 118 may be made of a material different from that of the cell insulating layer 132 selected from silicon, silicon oxide, silicon carbide, and silicon nitride. The thickness of the cell insulating layer 132 and the sacrificial insulating layer 118 and the number of membranes configuring the cell insulating layer 132 and the sacrificial insulating layer 118 may vary from those shown.

Subsequently, channel holes CHh penetrating the preliminary stack structure ST_P may be formed. For example, a second cell region insulating layer 132b may be formed that covers the preliminary stack structure ST_P formed of the sacrificial insulating layers 118 and the cell insulating layers 132. Next, openings corresponding to the channel holes CHh penetrating the second cell region insulating layer 132b and the preliminary stack structure ST_P may be formed. The channel holes CHh may be formed by etching the sacrificial insulating layers 118 and the cell insulating layers 132 included in the preliminary stack structure ST_P by using a mask layer. Due to the height of the preliminary stack structure ST_P, the lateral wall of the channel hole CHh may not be perpendicular to the top surface of the sacrificial substrate 101. The channel hole CHh may be formed to recess a portion of the sacrificial substrate 101.

Next, a channel structure CH may be formed within the channel hole CHh. Specifically, the blocking layer 156, the charge storage layer 154, the tunneling layer 152, the channel layer 140, and the core insulating layer 142 may be formed sequentially on the top surface of the second cell region insulating layer 132b and within the channel hole CHh. The blocking layer 156, the charge storage layer 154, the tunneling layer 152, and the channel layer 140 may be formed to have a uniform thickness by using an atomic layer deposition (ALD) process or a chemical vapor deposition (CVD) process. A core insulating layer 142 is formed to fill the interior of the channel structure CH and may be an insulating material. Subsequently, at least a portion of the channel structure CH may be planarized by using a chemical-mechanical polishing process.

Referring to FIG. 17, a plurality of gate electrodes 130 and a separation pattern WLC may be formed, and an upper wiring structure, a second junction structure 190, and a second inter-wiring insulating layer 192 may be formed on top of the gate stack structure 120.

First, openings penetrating the preliminary stack structure ST_P may be formed in the region corresponding to the separation pattern WLC, and a plurality of gate electrodes 130 may be formed.

For example, a mask layer including the openings may be formed on the channel structure CH. The openings may be formed to penetrate the preliminary stack structure ST_P formed of the sacrificial insulating layers 118 and the cell insulating layers 132. The opening may be formed to extend in the third direction (Z direction). Accordingly, the preliminary stack structure ST_P may be separated.

Next, the sacrificial insulating layer 118 exposed by the openings may be removed to form tunnel portions, and conductive material may be embedded within the tunneled portions to form the plurality of gate electrodes 130. The tunnel portions may be formed, for example, through a wet etch process that selectively removes the sacrificial insulating layer 118 relative to the cell insulating layers 132. The conductive material forming the plurality of gate electrodes 130 may include a metal, polycrystalline silicon, or metal silicide material. In this case, a gate dielectric layer may be formed together by depositing a dielectric layer having a conformal thickness prior to forming the plurality of gate electrodes 130.

Subsequently, the separation pattern WLC may be formed within the openings penetrating the preliminary stack structure ST_P in the region corresponding to the separation pattern WLC. The process of forming the separation pattern WLC may include filling the openings with an insulating material and then performing a planarization process to remove the mask layer and the insulating material. The insulating material may include silicon oxide, silicon nitride, or silicon oxynitride. However, the present disclosure is not limited thereto, and, in some implementations, the openings are filled with a conductive material along with the insulating material.

A select separation pattern SLC that penetrates at least a portion of the gate electrode 130 may be formed. For example, the select separation pattern SLC may be formed to penetrate the select gate electrodes 130S located at the top of the gate stack structure 120. By the select separation pattern SLC, the select gate electrodes 130S may be separated in the first direction (X direction).

Next, an upper wiring structure, a second junction structure 190, and a second inter-wiring insulating layer 192 may be formed on top of the gate stack structure 120. The upper wiring structure may include bit lines 182 and contact vias 180a. First, the contact via 180a may be formed to be connected with a channel pad 144 of the channel structure CH. The bit line 182 may be formed on the contact via 180a to be connected with the contact via 180a. Subsequently, a second inter-wire insulating layer 192 and a second junction structure 190 may be formed on the bit line 182. The second junction structure 190 may be made of copper, aluminum, tungsten, nickel, gold, tin, manganese, cobalt, titanium, tantalum, ruthenium, or an alloy thereof. In some implementations, the second junction structure 190 may include copper at least at the junction surface, such that the metal junction of the peripheral circuit structure PERI and the cell structure CELL may be configured as a copper-to-copper junction. However, the material of the second junction structure 190 is not limited to the foregoing.

Referring to FIGS. 18 and 19, the cell structure CELL may be bonded with a peripheral circuit structure PERI.

In some implementations, the peripheral circuit structure PERI includes a first substrate 210, circuit elements 220 located on the first substrate 210, first and second contact vias 234 and 236, and a first junction structure 290.

One surface of the peripheral circuit structure PERI adjacent to the cell structure CELL is a junction surface with the cell structure CELL, and be formed of a first junction structure 290 and a portion of the first inter-wire insulating layer 232 located around the first junction structure 290. One surface of the cell structure CELL adjacent to the peripheral circuit structure PERI is a junction surface with the peripheral circuit structure PERI, and may be formed of a second junction structure 190 and a portion of the second inter-wiring insulating layer 192 located around the second junction structure 190. Further, the second junction structure 190 may be electrically connected to the bit line 182. The first junction structure 290 may be electrically connected to the circuit element 220.

One surface of the cell structure CELL and one surface of the peripheral circuit structure PERI may be bonded by hybrid joining. For example, the first junction structure 290 of the peripheral circuit structure PERI and the second junction structure 190 of the cell structure CELL may be bonded in a direct contact state to form a metal junction. Further, a portion of the first inter-wiring insulating layer 232 of the peripheral circuit structure PERI and a portion of the second inter-wiring insulating layer 192 of the cell structure CELL may be bonded. However, the present disclosure is not limited thereto, and a separate junction insulating layer may be provided between the first inter-wiring insulating layer 232 and the second inter-wiring insulating layer 192, and portions of the junction insulating layers may be bonded to each other.

As such, the first junction structure 290 of the peripheral circuit structure PERI and the second junction structure 190 of the cell structure CELL may be bonded to provide an electrical connection path between the peripheral circuit structure PERI and the cell structure CELL. For example, the bit line 182 and/or gate electrode 130 connected to the channel structure CH via the first and second contact vias 236 and 234 may be electrically connected to the circuit element 220 of the peripheral circuit structure PERI.

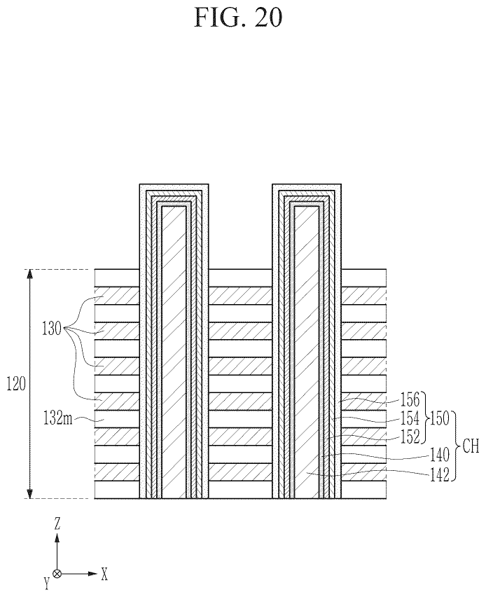

Referring to FIG. 20, the sacrificial substrate 101 may be removed to expose one end of the channel structure CH. For example, a planarization process and/or a recess process may be performed on the back side of the sacrificial substrate 101. This may allow the sacrificial substrate 101 to be removed, thereby exposing a blocking layer 156. In some implementations, at least a portion of the sacrificial substrate 101 is removed, such that the sacrificial substrate 101 remains on top of the top surface of the gate stack structure 120.

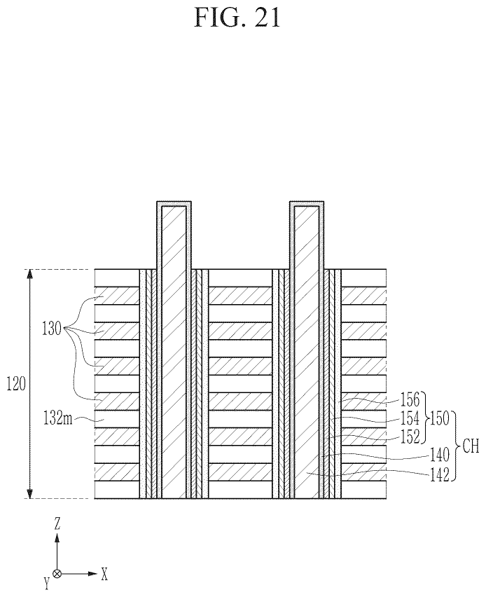

Referring to FIG. 21, at least a portion of the channel structure CH may be removed to expose one end of the channel layer 140. For example, a recess process may be performed on the blocking layer 156, the charge storage layer 154, and the tunneling layer 152. As the recess process is performed, at least a portion of one end (for example, the top end) of the exposed blocking layer 156, charge storage layer 154, and tunneling layer 152 may be sequentially removed. Through this, one end of the channel layer 140 may be exposed. For example, a top surface of the channel layer 140 and a portion of a lateral surface of the channel layer 140 may be exposed.

A recess process may be performed variously on the blocking layer 156, the charge storage layer 154, and the tunneling layer 152. For example, the exposed top surface of the channel layer 140 may be located at a higher level than the top surface of the cell insulating layer 132. For example, the exposed top surface of the channel layer 140 may be located further from the top surface of the first substrate 210 than the top surface of the cell insulating layer 132.

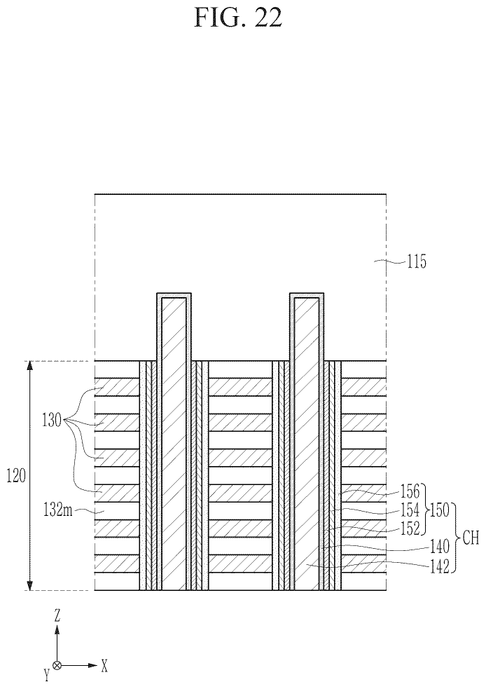

Referring to FIG. 22, a substrate insulating layer 115 may be formed on top of the cell insulating layer 132 and the exposed channel layer 140. For example, the cell insulating layer 132 may be formed to cover the top surface of the cell insulating layer 132, the top surface of the exposed channel layer 140, and the lateral surface of the exposed channel layer 140.

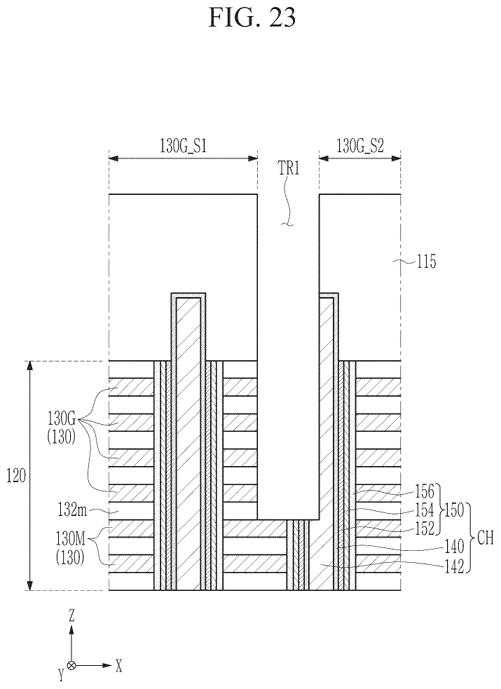

Referring to FIG. 23, a first trench TR1 that penetrates at least a portion of the substrate insulating layer 115 may be formed. For example, a first trench TR1 that penetrates at least a portion of the substrate insulating layer 115 and at least a portion of the gate stack structure 120 may be formed. For example, as illustrated in FIG. 23, a first trench TR1 that penetrates four gate electrodes 130 and four interlayer insulating layers 132m located on the upper portion of the gate stack structure 120 may be formed, but the present disclosure is not limited thereto. Accordingly, the lateral surfaces of the gate electrodes 130, the lateral surfaces of the interlayer insulating layers 132m, and the lateral surface of the substrate insulating layer 115 may be exposed.

In this case, the plurality of gate electrodes 130 penetrated by the first trench TR1 may be ground gate electrodes 130G. For example, the first trench TR1 may penetrate the ground gate electrodes 130G located in the upper portion of the gate stack structure 120. Accordingly, the ground gate electrodes 130G may be separated into a first portion 130G_S1 and a second portion 130G_S2 by the first trench TR1. Accordingly, the first portion 130G_S1 and the second portion 130G_S2 of the ground gate electrode 130G may be electrically insulated.

The first trench TR1 may penetrate at least a portion of the channel structure CH. For example, the first trench TR1 may penetrate at least portions of the channel layer 140 and the core insulating layer 142, which protrude from the top surface of the gate stack structure 120. Further, the first trench TR1 may penetrate at least portions of the blocking layer 156, the charge storage layer 154, the tunneling layer 152, the channel layer 140, and the core insulating layer 142. Accordingly, the top surfaces of the blocking layer 156, the charge storage layer 154, the tunneling layer 152, and the channel layer 140 may be exposed by the first trench TR1. Additionally, the lateral surface of the core insulating layer 142 may be exposed by the first trench TR1.

The first trench TR1 may have a zigzag shape in a plane formed by the first direction (X direction) and the second direction (Y direction). For example, the first trench TR1 may have a zigzag shape along the second direction (Y direction) between the separation patterns WLC. In a plane, the first trench TR1 may include a first extending portion extending in a first diagonal direction intersecting the first direction (X direction) and the second direction (Y direction) and a second extending portion extending in a second diagonal direction intersecting the first direction (X direction), the second direction (Y direction), and the first diagonal direction. In the plane, the first extending portion and the second extending portion may be located alternately along the second direction (Y direction).

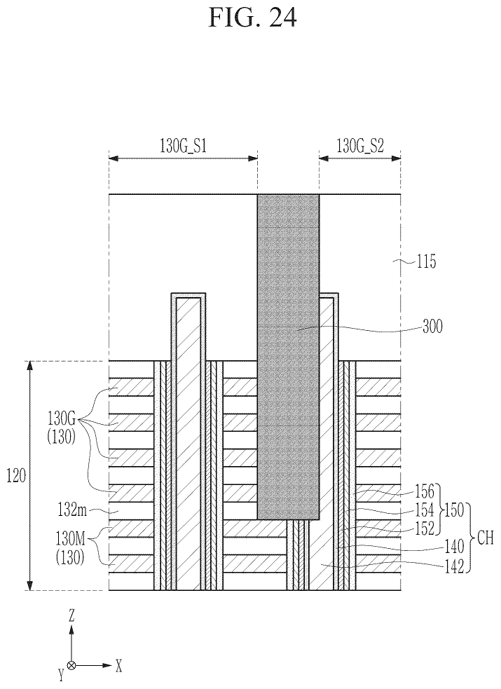

Referring to FIG. 24, the separation structure 300 may be formed within the first trench TR1. The process of forming the separation structure 300 may include filling the top surface of the substrate insulating layer 115 and the first trench TR1 with an insulating material and then performing a planarization process to remove the insulating material located on the top surface of the substrate insulating layer 115. The separation structure 300 may include various insulating materials. For example, the separation structure 300 may include silicon oxide, silicon nitride, silicon oxynitride, silicon carbon oxide, silicon carbonitride, or combinations thereof, but the present disclosure is not limited thereto.

The separation structure 300 may penetrate at least a portion of the channel structure CH. For example, the separation structure 300 may penetrate at least portions of the blocking layer 156, the charge storage layer 154, the tunneling layer 152, the channel layer 140, and the core insulating layer 142. Accordingly, the separation structure 300 may be in contact with the blocking layer 156, the charge storage layer 154, the tunneling layer 152, the channel layer 140, and the core insulating layer 142. The separation structure 300 may overlap the blocking layer 156, the charge storage layer 154, the tunneling layer 152, the channel layer 140, and the core insulating layer 142 in the third direction (Z direction).

The separation structure 300 may have a zigzag shape in a plane formed by the first direction (X direction) and the second direction (Y direction). For example, the separation structure 300 may have a zigzag shape along the second direction (Y direction) between the separation patterns WLC. Further, the separation structure 300 may have a zigzag shape along the second direction (Y direction) to overlap with the channel structure CH. The remainder of the description of the separation structure 300 is substantially the same as the description of the separation structure 300 of the example of FIGS. 1 to 5, and will therefore be omitted.

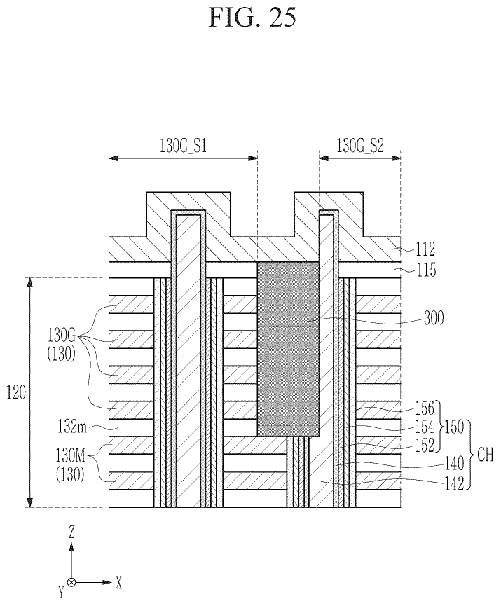

Referring to FIG. 25, at least the portions of the substrate insulating layer 115 and the separation structure 300 may be removed, and a common source electrode 112 may be formed on the substrate insulating layer 115.

First, the substrate insulating layer 115 and at least a portion of the separation structure 300 may be removed. In this case, the portion of the substrate insulating layer 115 that is located on the channel structure CH may be removed to expose the channel structure CH. For example, a top surface of the channel layer 140, a lateral surface of the channel layer 140, and a lateral surface of the core insulating layer 142 may be exposed. The process of removing the substrate insulating layer 115 and at least the portion of the separation structure 300 may be performed by a wet etch or dry etch process, but the present disclosure is not limited thereto. Additionally, the process of planarizing at least a portion of the substrate insulating layer 115 by using a chemical-mechanical polishing process may be further included.

A common source electrode 112 may then be formed on the top surface of the substrate insulating layer 115, the exposed top surface and lateral surface of the channel layer 140, the top surface of the separation structure 300, and the lateral surface of the core insulating layer 142. The common source electrode 112 may be formed with a conformal thickness to cover the top surface and the lateral surface of the channel layer 140. However, the present disclosure is not limited thereto, and the common source electrode 112 may be formed with a thickness sufficient to cover the top surface and the lateral surface of the channel layer 140.

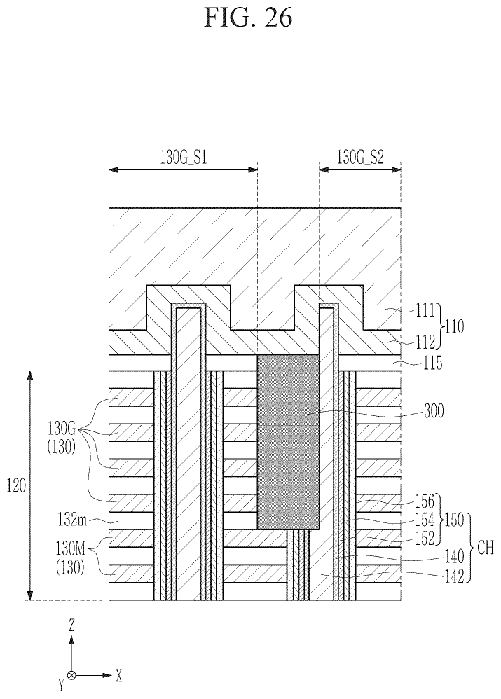

Referring to FIG. 26, the insulating pattern 111 may be formed on the common source electrode 112 to form a semiconductor device.

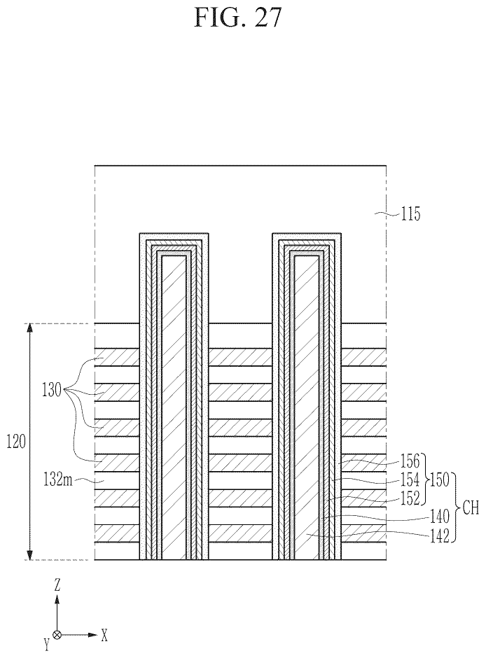

Hereinafter, a method of manufacturing a semiconductor device according to some implementations will be described with reference to FIGS. 27 to 31.

FIGS. 27 to 31 are cross-sectional views corresponding to region P3 of FIG. 18, illustrating intermediate operations in the method of manufacturing a semiconductor device. The method and the device can have characteristics as described with respect to FIGS. 16 to 26, except where noted otherwise or suggested otherwise by context.

Referring to FIG. 27, after forming the cell structure CELL, the cell structure CELL and the peripheral circuit structure PERI may be bonded, and the sacrificial substrate 101 may be removed. The substrate insulating layer 115 may then be formed on the exposed gate stack structure 120.

The process of bonding the cell structure CELL to the peripheral circuit structure PERI and removing the sacrificial substrate 101 after forming the cell structure CELL is substantially the same as described for FIGS. 16 to 26, so the description thereof will be omitted.

In some implementations, the sacrificial substrate 101 is removed, so that the top surface of the gate stack structure 120 and one end of the channel structure CH are exposed. For example, the top surface and the lateral surface of the blocking layer 156 may be exposed. For example, a planarization process and/or a recess process may be performed on the back side of the sacrificial substrate 101. This may allow the sacrificial substrate 101 to be removed, thereby exposing a blocking layer 156. In some implementations, at least a portion of the sacrificial substrate 101 is removed, such that the sacrificial substrate 101 remains on top of the top surface of the gate stack structure 120.

The substrate insulating layer 115 may be formed on the top surface and the lateral surface of the exposed blocking layer 156 and on the top surface of the gate stack structure 120. For example, the cell insulating layer 132 may be formed to cover the top surface of the cell insulating layer 132, the exposed top surface of the channel layer 140, and the exposed lateral surface of the channel layer 140.

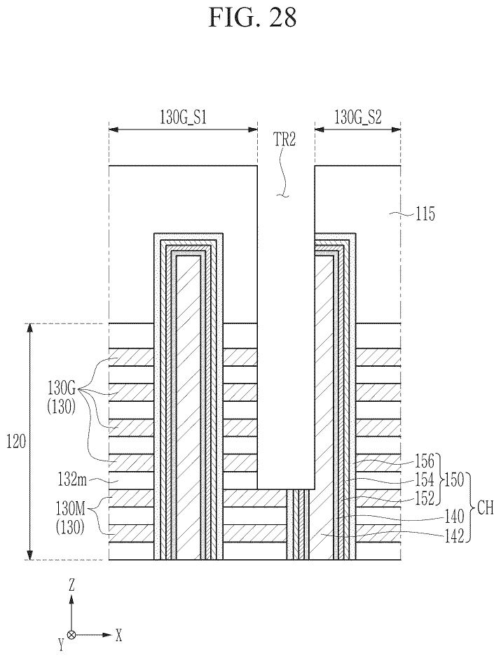

Referring to FIG. 28, a second trench TR2 that penetrates at least a portion of the substrate insulating layer 115 may be formed. For example, a second trench TR2 that penetrates at least a portion of the substrate insulating layer 115 and at least a portion of the gate stack structure 120 may be formed. For example, as illustrated in FIG. 23, the second trench TR2 that penetrates four gate electrodes 130 and four interlayer insulating layers 132m located on the upper portion of the gate stack structure 120 may be formed, but the present disclosure is not limited thereto. Accordingly, the lateral surfaces of the gate electrodes 130, the lateral surfaces of the interlayer insulating layers 132m, and the lateral surface of the substrate insulating layer 115 may be exposed.

In this case, the plurality of gate electrodes 130 penetrated by the second trench TR2 may be ground gate electrodes 130G. For example, the second trench TR2 may penetrate the ground gate electrodes 130G located in the upper portion of the gate stack structure 120. Accordingly, the ground gate electrodes 130G may be separated into a first portion 130G_S1 and a second portion 130G_S2 by the second trench TR2. Accordingly, the first portion 130G_S1 and the second portion 130G_S2 of the ground gate electrode 130G may be electrically insulated or isolated from one another.

The second trench TR2 may penetrate at least a portion of the channel structure CH. For example, the second trench TR2 may penetrate at least portions of the blocking layer 156, the charge storage layer 154, the tunneling layer 152, the channel layer 140, and the core insulating layer 142, which protrude from the top surface of the gate stack structure 120. Further, the second trench TR2 may penetrate at least portions of the blocking layer 156, the charge storage layer 154, the tunneling layer 152, the channel layer 140, and the core insulating layer 142, which are located under the top surface of the gate stack structure 120. Accordingly, the lateral surfaces of the blocking layer 156, the charge storage layer 154, the tunneling layer 152, the channel layer 140, and the core insulating layer 142 may be exposed by the second trench TR2.

The second trench TR2 may have a zigzag shape in a plane formed of the first direction (X direction) and the second direction (Y direction). For example, the second trench TR2 may have a zigzag shape along the second direction (Y direction) between the separation patterns WLC. In the plane, the second trench TR2 may include a first extending portion extending in a first diagonal direction intersecting the first direction (X direction) and the second direction (Y direction) and a second extending portion extending in a second diagonal direction intersecting the first direction (X direction), the second direction (Y direction), and the first diagonal direction. The first extending portion and the second extending portion may be located alternately along the second direction (Y direction).

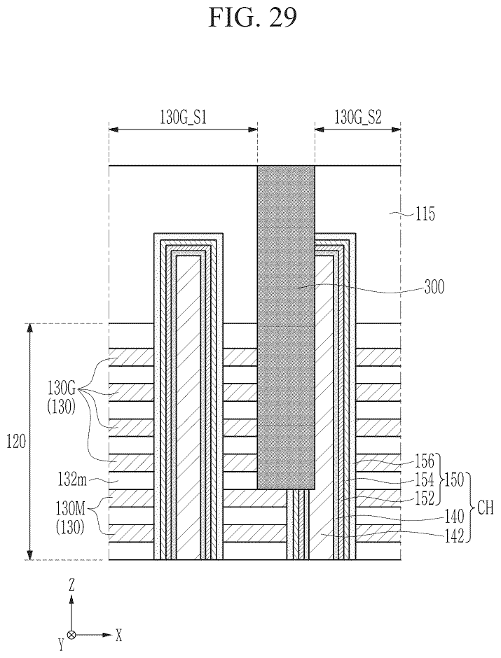

Referring to FIG. 29, the separation structure 300 may be formed within the second trench TR2. The process of forming the separation structure 300 may include filling the top surface of the substrate insulating layer 115 and the second trench TR2 with an insulating material and then performing a planarization process to remove the insulating material located on the top surface of the substrate insulating layer 115. The separation structure 300 may include various insulating materials. For example, the separation structure 300 may include silicon oxide, silicon nitride, silicon oxynitride, silicon carbon oxide, silicon carbonitride, or combinations thereof, but the present disclosure is not limited thereto.

The separation structure 300 may penetrate at least a portion of the channel structure CH. For example, the separation structure 300 may penetrate at least portions of the blocking layer 156, the charge storage layer 154, the tunneling layer 152, the channel layer 140, and the core insulating layer 142. Accordingly, the separation structure 300 may be in contact with the blocking layer 156, the charge storage layer 154, the tunneling layer 152, the channel layer 140, and the core insulating layer 142. The separation structure 300 may overlap the blocking layer 156, the charge storage layer 154, the tunneling layer 152, the channel layer 140, and the core insulating layer 142 in the third direction (Z direction).

The separation structure 300 may have a zigzag shape in a plane formed of the first direction (X direction) and the second direction (Y direction). For example, the separation structure 300 may have a zigzag shape along the second direction (Y direction) between the separation patterns WLC. Further, the separation structure 300 may have a zigzag shape along the second direction (Y direction) to overlap with the channel structure CH. The remainder of the description of the separation structure 300 is substantially the same as the description of the separation structure 300 described with respect to FIGS. 1 to 5, and will therefore be omitted.

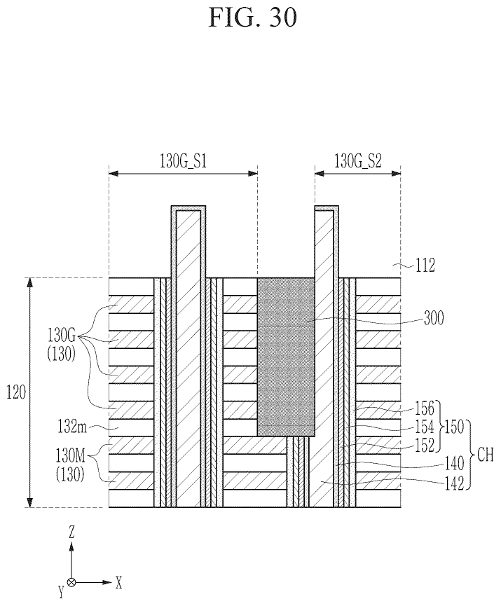

Referring to FIG. 30, at least portions of the substrate insulating layer 115, the separation structure 300, and the channel structure CH may be removed.

First, the substrate insulating layer 115 may be removed, and then at least a portion of the separation structure 300 may be removed. The process of removing the substrate insulating layer 115 and at least the portion of the separation structure 300 may be performed by a wet etch or dry etch process, but the present disclosure is not limited thereto. Additionally, the process of planarizing at least a portion of the substrate insulating layer 115 by using a chemical-mechanical polishing process may be further included. Accordingly, the top surface of the gate stack structure 120 may be exposed. Furthermore, the top surface of the separation structure 300 may be located substantially at the same level as the top surface of the gate stack structure 120.

At least portions of the channel structure CH may be removed together with the substrate insulating layer 115 and the separation structure 300. For example, the blocking layer 156, the charge storage layer 154, and the tunneling layer 152 that protrude from the top surface of the gate stack structure 120 may be removed together. However, the present disclosure is not limited thereto, and after removing the substrate insulating layer 115 and at least a portion of the separation structure 300, the blocking layer 156, the charge storage layer 154, and the tunneling layer 152 protruding from the top surface of the gate stack structure 120 may be removed in a separate process.

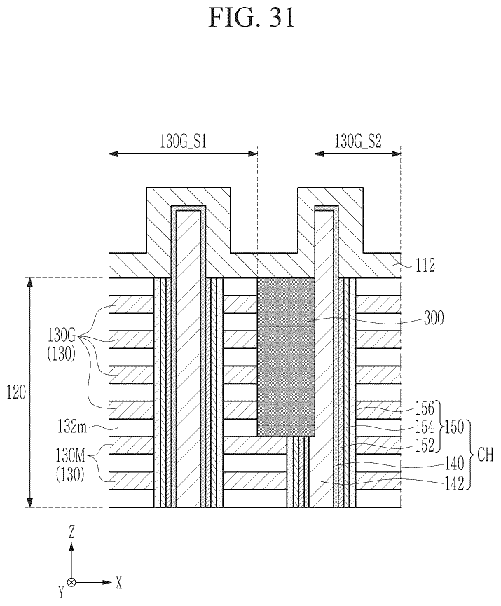

Referring to FIG. 31, a common source electrode 112 may be formed on the top surface of the exposed gate stack structure 120, the exposed top surface of the separation structure 300, the exposed top surface and the lateral surface of the channel layer 140, and the exposed lateral surface of the core insulating layer 142. The common source electrode 112 may be formed with a conformal thickness to cover the top surface and the lateral surface of the channel layer 140. However, the present disclosure is not limited thereto, and the common source electrode 112 may be formed with a thickness sufficient to cover the top surface and the lateral surface of the channel layer 140. Subsequently, an insulating pattern 111 may be formed on the common source electrode 112 to form a semiconductor device.

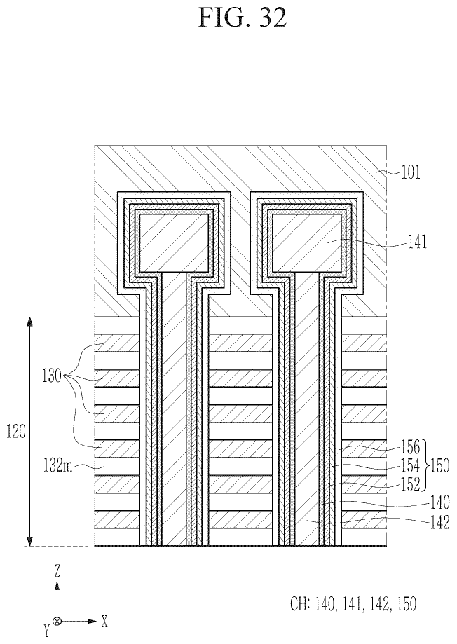

Hereinafter, a method of manufacturing a semiconductor device will be described with reference to FIGS. 32 to 39. FIGS. 32 to 39 are cross-sectional views corresponding to region P3 of FIG. 18, illustrating intermediate operations in a method of manufacturing a semiconductor device. Hereinafter, aspects of the operations that are identical to those of the example of FIGS. 16 to 26 will be indicated by the same reference numerals, and redundant descriptions will be omitted or simplified; differences will be mainly described, such that the characteristics can be the same except where noted otherwise or suggested otherwise by context.

Referring to FIG. 32, after forming a cell structure CELL, the cell structure CELL and a peripheral circuit structure PERI may be bonded together.

In some implementations, the channel structure CH of the cell structure CELL further includes a stopper pattern 141. The stopper pattern 141 may be embedded within a sacrificial substrate 101. A width along a horizontal direction (for example, the first direction (X direction) and/or the second direction (Y direction)) of the stopper pattern 141 may be greater than a width along a horizontal direction (for example, the first direction (X direction) and/or the second direction (Y direction) of the core insulating layer 142, but the present disclosure is not limited thereto. The stopper pattern 141 may overlap the core insulating layer 142 in the third direction (Z direction). At least a portion of a bottom surface of the stopper pattern 141 may be in contact with the core insulating layer 142. The stopper pattern 141 may function as a stopper to prevent the second substrate 110 from being penetrated in the process of forming a channel hole (CHh in FIG. 16) penetrating the gate stack structure 120 and penetrating at least a portion of the sacrificial substrate 101.

In some implementations, the channel layer 140, the tunneling layer 152, the charge storage layer 154, and the blocking layer 156 sequentially surround the stopper pattern 141. For example, the channel layer 140, the tunneling layer 152, the charge storage layer 154, and the blocking layer 156 may surround the top surface, the lateral surface, and a portion of the bottom surface of the stopper pattern 141.

The process of bonding the cell structure CELL to the peripheral circuit structure PERI after forming the cell structure CELL is substantially the same as in the description of FIGS. 16 to 26, so that the description thereof will be omitted.

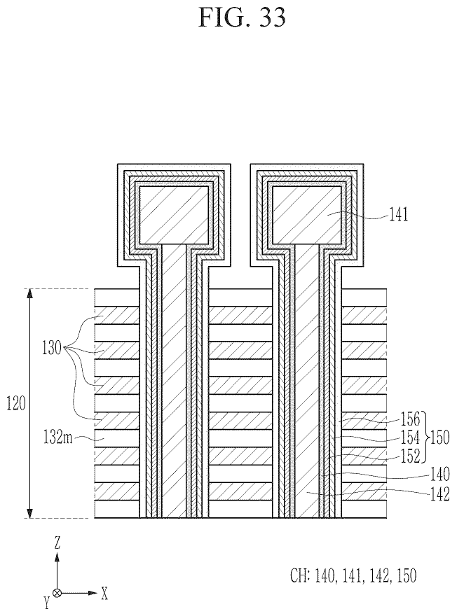

Referring to FIG. 33, the sacrificial substrate 101 may be removed to expose one end of the channel structure CH. For example, a planarization process and/or a recess process may be performed on the back side of the sacrificial substrate 101. This may allow the sacrificial substrate 101 to be removed, thereby exposing a blocking layer 156. In some implementations, at least a portion of the sacrificial substrate 101 is removed, such that the sacrificial substrate 101 remains on top of the top surface of the gate stack structure 120.

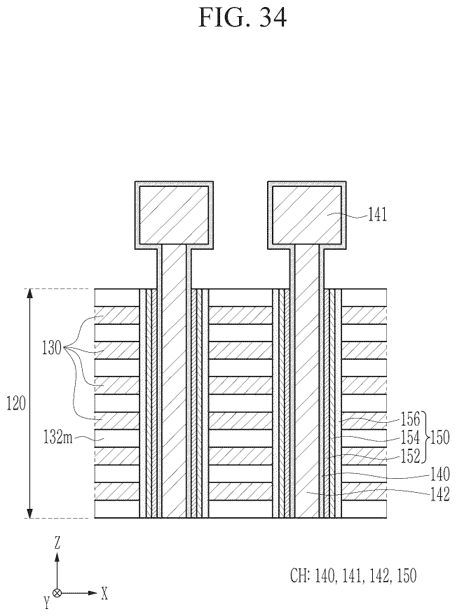

Referring to FIG. 34, at least a portion of the channel structure CH may be removed to expose one end of the channel layer 140. For example, a recess process may be performed on the blocking layer 156, the charge storage layer 154, and the tunneling layer 152. As the recess process is performed, at least a portion of one end (for example, the top end) of the exposed blocking layer 156, charge storage layer 154, and tunneling layer 152 may be sequentially removed. Accordingly, one end of the channel layer 140 may be exposed. For example, the top surface of the channel layer 140, a portion of the lateral surface of the channel layer 140, and a portion of the bottom surface of the channel layer 140 may be exposed. In this case, at least a portion of the interlayer insulating layer 132m located in the upper portion of the exposed gate stack structure 120 may be removed together, but the present disclosure is not limited thereto.

For example, a recess process may be performed variously on the blocking layer 156, the charge storage layer 154, and the tunneling layer 152. For example, the exposed top surface of the channel layer 140 may be located at a higher level than the top surface of the cell insulating layer 132. For example, the exposed top surface of the channel layer 140 may be located further from the top surface of the first substrate 210 than the top surface of the cell insulating layer 132.

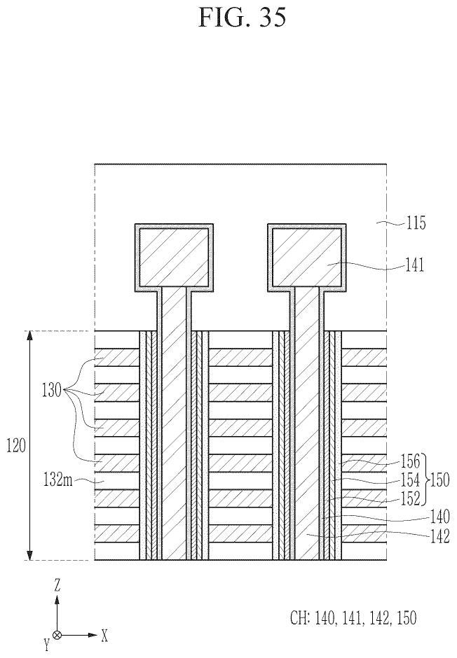

Referring to FIG. 35, a substrate insulating layer 115 may be formed on top of the cell insulating layer 132 and the exposed channel layer 140. For example, the cell insulating layer 132 may be formed to cover the top surface of the cell insulating layer 132, the top surface of the exposed channel layer 140, and the lateral surface of the exposed channel layer 140.

Referring to FIG. 36, a third trench TR3 that penetrates at least a portion of the substrate insulating layer 115 may be formed. For example, the third trench TR3 that penetrates at least a portion of the substrate insulating layer 115 and at least a portion of the gate stack structure 120 may be formed. The description of the third trench TR3 is substantially the same as the description of the first trench TR1 in FIGS. 16 through 26, and will therefore be omitted.

The third trench TR3 may penetrate at least a portion of the channel structure CH. For example, the third trench TR3 may penetrate at least portions of the channel layer 140, the stopper pattern 141, and the core insulating layer 142 which protrude from the top surface of the gate stack structure 120. Further, the third trench TR3 may penetrate at least portions of the blocking layer 156, the charge storage layer 154, the tunneling layer 152, the channel layer 140, and the core insulating layer 142. Accordingly, the top surfaces of the blocking layer 156, the charge storage layer 154, the tunneling layer 152, and the channel layer 140 may be exposed by the third trench TR3. Additionally, a lateral surface of the stopper pattern 141 and a lateral surface of the core insulating layer 142 may be exposed by the third trench TR3.

The third trench TR3 may have a zigzag shape in a plane formed by the first direction (X direction) and the second direction (Y direction). For example, the third trench TR3 may have a zigzag shape along the second direction (Y direction) between the separation patterns WLC. In the plane, the third trench TR3 may include a first extending portion extending in a first diagonal direction intersecting the first direction (X direction) and the second direction (Y direction) and a second extending portion extending in a second diagonal direction intersecting the first direction (X direction), the second direction (Y direction), and the first diagonal direction. The first extending portion and the second extending portion may be located alternately along the second direction (Y direction).

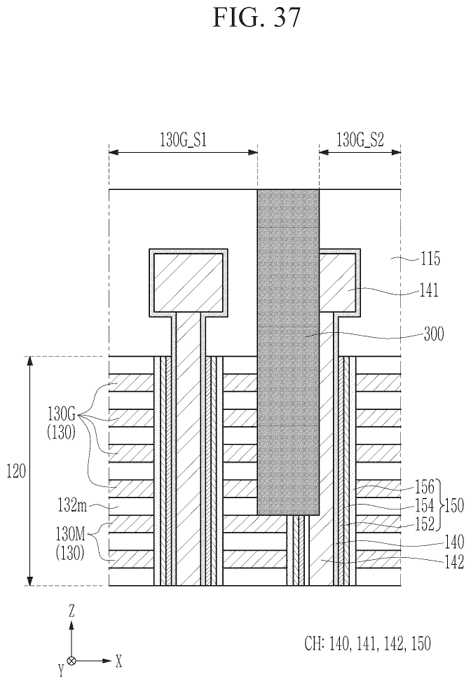

Referring to FIG. 37, the separation structure 300 may be formed within the third trench TR3. The process of forming the separation structure 300 may include filling the top surface of the substrate insulating layer 115 and the third trench TR3 with an insulating material and then performing a planarization process to remove the insulating material located on the top surface of the substrate insulating layer 115. The separation structure 300 may include various insulating materials. For example, the separation structure 300 may include silicon oxide, silicon nitride, silicon oxynitride, silicon carbon oxide, silicon carbonitride, or combinations thereof, but the present disclosure is not limited thereto.

The separation structure 300 may penetrate at least a portion of the channel structure CH. For example, the separation structure 300 may penetrate at least portions of the stopper pattern 141, the blocking layer 156, the charge storage layer 154, the tunneling layer 152, the channel layer 140, and the core insulating layer 142. Accordingly, the separation structure 300 may be in contact with the stopper pattern 141, the blocking layer 156, the charge storage layer 154, the tunneling layer 152, the channel layer 140, and the core insulating layer 142. The separation structure 300 may overlap the blocking layer 156, the charge storage layer 154, the tunneling layer 152, the channel layer 140, and the core insulating layer 142 in the third direction (Z direction).

The separation structure 300 may have a zigzag shape in a plane formed by the first direction (X direction) and the second direction (Y direction). For example, the separation structure 300 may have a zigzag shape along the second direction (Y direction) between the separation patterns WLC. Further, the separation structure 300 may have a zigzag shape along the second direction (Y direction) to overlap with the channel structure CH. The remainder of the description of the separation structure 300 is substantially the same as the description of the separation structure 300 of FIGS. 1 to 5, and will therefore be omitted.

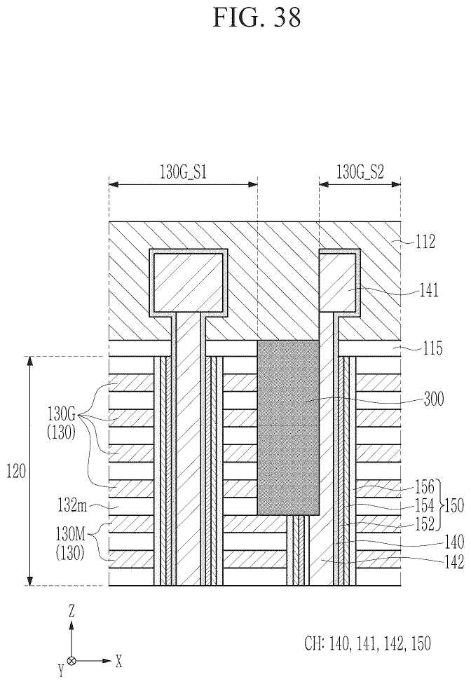

Referring to FIG. 38, the substrate insulating layer 115 and at least a portion of the separation structure 300 may be removed, and a common source electrode 112 may be formed on the substrate insulating layer 115.

First, the substrate insulating layer 115 and at least a portion of the separation structure 300 may be removed. In this case, the portion of the substrate insulating layer 115 that is located on the channel structure CH may be removed to expose the channel structure CH. For example, the lateral surface of the stopper pattern 141, a top surface of the channel layer 140, a lateral surface of the channel layer 140, and a lateral surface of the core insulating layer 142 may be exposed. The process of removing the substrate insulating layer 115 and at least the portion of the separation structure 300 may be performed by a wet etch or dry etch process, but the present disclosure is not limited thereto. Additionally, the process of planarizing at least a portion of the substrate insulating layer 115 by using a chemical-mechanical polishing process may be further included.

Subsequently, a common source electrode 112 may then be formed on the lateral surface of the stopper pattern 141, the top surface of the substrate insulating layer 115, the exposed top surface and lateral surface of the exposed channel layer 140, the top surface of the separation structure 300, and the lateral surface of the core insulating layer 142. The common source electrode 112 may be formed with a thickness sufficient to cover the top surface and the lateral surface of the channel layer 140.

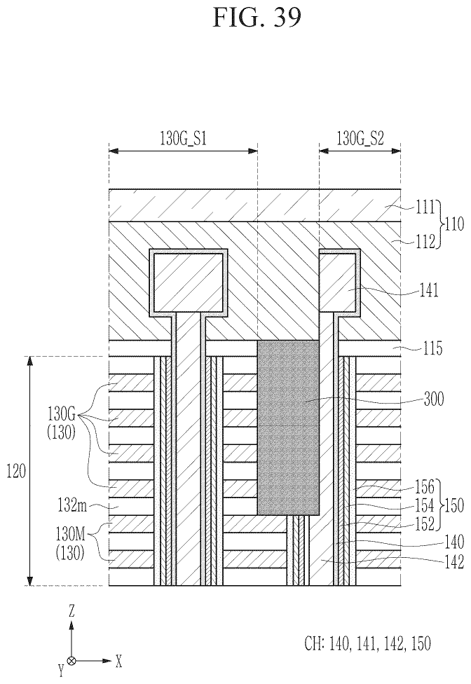

Referring to FIG. 39, the insulating pattern 111 may be formed on the common source electrode 112 to form a semiconductor device.

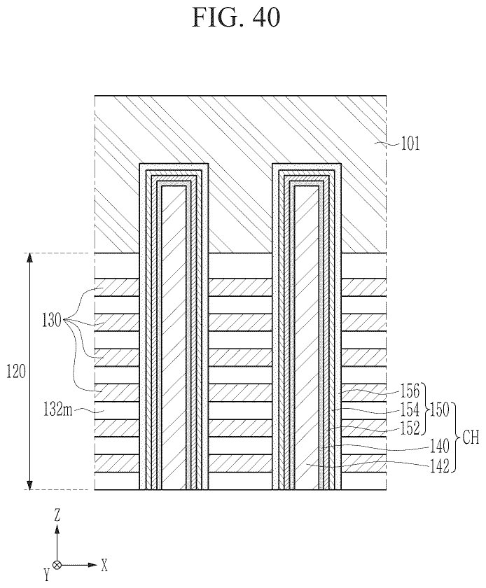

Hereinafter, a method of manufacturing a semiconductor device will be described with reference to FIGS. 40 to 44. FIGS. 40 to 44 are cross-sectional views corresponding to region P3 of FIG. 18, illustrating intermediate operations in the method of manufacturing the semiconductor device. Hereinafter, characteristics that are identical to those of the examples of FIGS. 16 to 26 will be indicated by the same reference numerals, and redundant descriptions will be omitted or simplified and differences will be mainly described; the method and device can have the characteristics described with respect to FIGS. 16 to 26, except where noted otherwise or suggested otherwise by context.

Referring to FIG. 40, after forming a cell structure CELL, the cell structure CELL and a peripheral circuit structure PERI may be bonded.

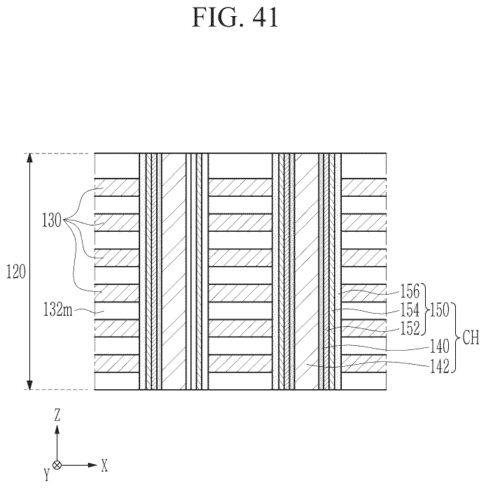

Referring to FIG. 41, a sacrificial substrate 101 may be removed. The process of removing the sacrificial substrate 101 may be performed by using a chemical-mechanical polishing process. In this case, at least a portion of the channel structure CH may be removed together with the sacrificial substrate 101. For example, the portion of the channel structure CH that overlaps the sacrificial substrate 101 in a horizontal direction (first direction (X direction) and/or second direction (Y direction)) may be removed along with the sacrificial substrate 101 in the process of removing the sacrificial substrate 101.

In some implementations, by removing the sacrificial substrate 101 and at least a portion of the channel structure CH, a top surface of the gate stack structure 120 and one end of the channel structure CH is exposed. For example, the top surface of the blocking layer 156, the top surface of the charge storage layer 154, the top surface of the tunneling layer 152, the top surface of the channel layer 140, and the top surface of the core insulating layer 142 may be exposed. In some implementations, at least a portion of the sacrificial substrate 101 is removed, such that the sacrificial substrate 101 remains on top of the top surface of the gate stack structure 120.

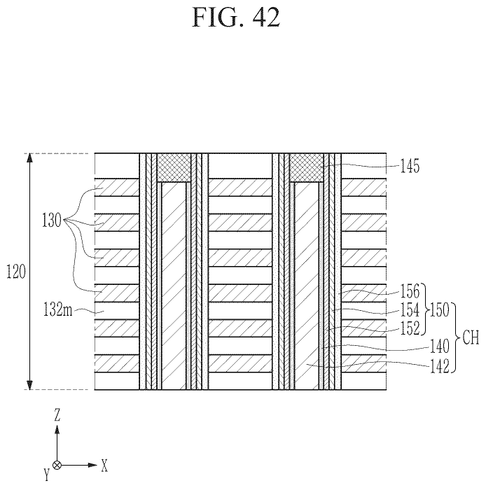

Referring to FIG. 42, at least a portion of the exposed channel structure CH may be removed, and an upper channel pad 145 may be formed within the removed space.

First, at least portions of the exposed channel layer 140 and core insulating layer 142 may be etched. The process of removing at least the portions of the channel layer 140 and the core insulating layer 142 may be performed by a wet etch or dry etch process, but the present disclosure is not limited thereto. An upper channel pad 145 may then be formed within the removed space. The upper channel pad 145 may include the same material as the channel layer 140. For example, the upper channel pad 145 may include polycrystalline silicon. However, the present disclosure is not limited thereto, and the upper channel pad 145 may also include a different material from the channel layer 140. The top surface of the upper channel pad 145 may be located at the same level as the top surface of the gate stack structure 120.

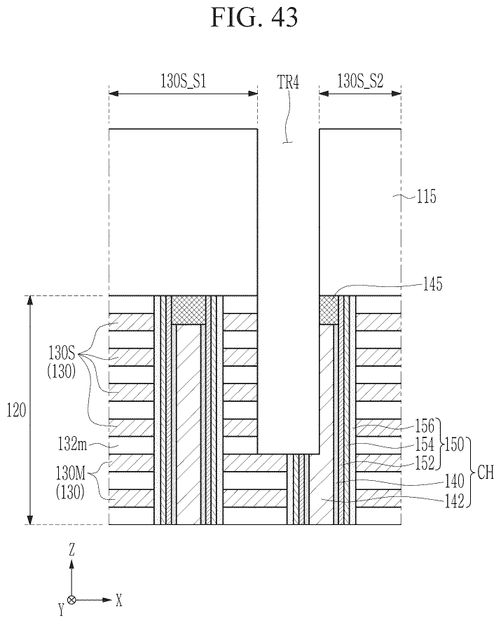

Referring to FIG. 43, a substrate insulating layer 115 may first be formed on the exposed upper channel pad 145 and the gate stack structure 120.

The substrate insulating layer 115 may be formed on the exposed top surface of the blocking layer 156, the exposed top surface of the charge storage layer 154, the exposed top surface of the tunneling layer 152, the exposed top surface of the upper channel pad 145, and the exposed top surface of the gate stack structure 120. For example, the substrate insulating layer 115 may be formed to cover the top surface of the cell insulating layer 132 and the top surface of the upper channel pad 145.

Subsequently, a fourth trench TR4 penetrating at least a portion of the substrate insulating layer 115 may be formed. Specifically, the fourth trench TR4 penetrating the substrate insulating layer 115 and at least a portion of the gate stack structure 120 may be formed. For example, as illustrated in FIG. 43, the fourth trench TR4 that penetrates four gate electrodes 130 and four interlayer insulating layers 132m located on the upper portion of the gate stack structure 120 may be formed, but the present disclosure is not limited thereto. Accordingly, the lateral surfaces of the gate electrodes 130, the lateral surfaces of the interlayer insulating layers 132m, and the lateral surface of the substrate insulating layer 115 may be exposed.

In this case, the plurality of gate electrodes 130 penetrated by the fourth trench TR4 may be select gate electrodes 130S. For example, the fourth trench TR4 may penetrate the select gate electrodes 130S located in the upper portion of the gate stack structure 120. Accordingly, the select gate electrodes 130S may be separated into a first portion 130S_S1 and a second portion 130S_S2 by the fourth trench TR4. Accordingly, the first portion 130S_S1 and the second portion 130S_S2 of the select gate electrode 130S may be electrically insulated or isolated from one another.

In some implementations, the fourth trench TR4 penetrates at least a portion of the channel structure CH. For example, the fourth trench TR4 may penetrate at least portions of the blocking layer 156, the charge storage layer 154, the tunneling layer 152, the channel layer 140, and the core insulating layer 142. Further, the fourth trench TR4 may penetrate at least a portion of the upper channel pad 145. Accordingly, the lateral surfaces of the blocking layer 156, the charge storage layer 154, the tunneling layer 152, the channel layer 140, the core insulating layer 142, and the upper channel pad 145 may be exposed by the fourth trench TR4.

The fourth trench TR4 may have a zigzag shape in a plane formed by the first direction (X direction) and the second direction (Y direction). The description of the fourth trench TR4 is substantially the same as the description of the first trench (TR1 of FIG. 23) of the example of FIGS. 16 to 26, and will therefore be omitted.

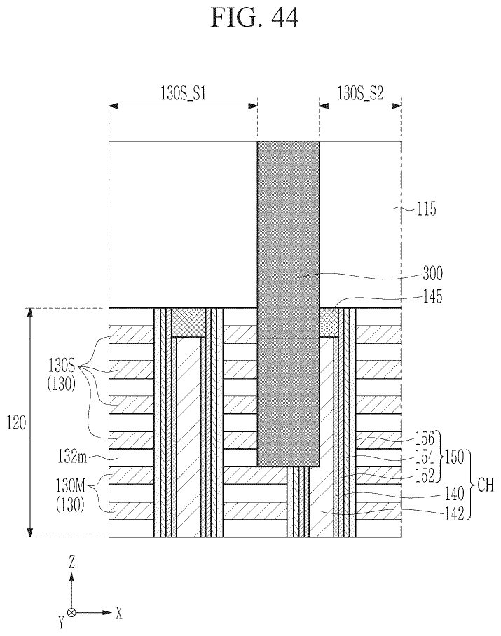

Referring to FIG. 44, a separation structure 300 may be formed within the fourth trench TR4 to form a semiconductor device.

The process of forming the separation structure 300 may include filling the top surface of the substrate insulating layer 115 and the fourth trench TR4 with an insulating material and then performing a planarization process to remove the insulating material located on the top surface of the substrate insulating layer 115. The remainder of the description of the separation structure 300 is substantially the same as the description of the separation structure 300 of the example of FIGS. 16 to 26, and will therefore be omitted.

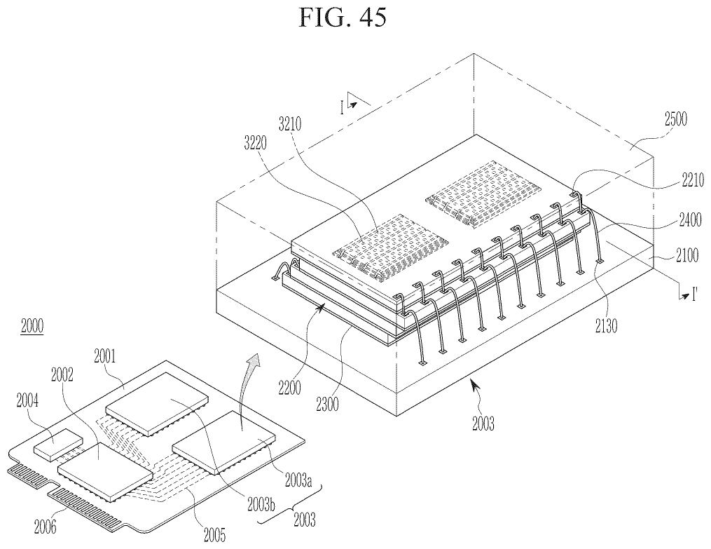

Hereinafter, one example of an electronic system including a semiconductor device as described above will be described in detail with reference to FIGS. 45 to 47.

FIG. 46 is a diagram schematically illustrating an electronic system including any of the foregoing semiconductor devices described with respect to FIGS. 1 to 44.

Referring to FIG. 46, an electronic system 1000 includes a semiconductor device 1100 and a controller 1200 electrically connected to the semiconductor device 1100. The electronic system 1000 may be a storage device including one or more semiconductor devices 1100 or an electronic device including a storage device. For example, the electronic system 1000 may be a solid state drive (SSD) device, a universal serial bus (USB), a computing system, a medical device, or a communication device that includes one or more semiconductor devices 1100.

The semiconductor device 1100 may be a non-volatile memory device, for example, a NAND flash memory device as described with reference to FIGS. 1 to 15. The semiconductor device 1100 may include a first structure 1100F and a second structure 1100S on the first structure 1100F. In some implementations, the first structure 1100F is disposed next to the second structure 1100S. The first structure 1100F may be a peripheral circuit structure including a decoder circuit 1110, a page buffer 1120, and a logic circuit 1130. The second structure 1100S may be a memory cell structure including a bitline BL, a common source line CSL, a wordline WL, first and second gate upper lines UL1 and UL2, first and second gate lower lines LL1 and LL2, and a memory cell string CSTR between the bitline BL and the common source line CSL.

In the second structure 1100S, each memory cell string CSTR may include lower transistors LT1 and LT2 adjacent to the common source line CSL, upper transistors UT1 and UT2 adjacent to the bitline BL, and a plurality of memory cell transistors MCTs disposed between the lower transistors LT1 and LT2 and the upper transistors UT1 and UT2. The number of lower transistors LT1 and LT2 and the number of upper transistors UT1 and UT2 may vary in various implementations.

In some implementations, the lower transistors LT1 and LT2 include ground select transistors, and the upper transistors UT1 and UT2 may include string select transistors. The first and second gate lower lines LL1 and LL2 may be gate electrodes of the lower transistors LT1 and LT2, respectively. The wordline WL may be the gate electrode of a memory cell transistor MCT, and the gate upper lines UL1 and UL2 may be the gate electrodes of upper transistors UT1 and UT2, respectively.

The common source lines CSL, the first and second gate lower lines LL1 and LL2, the word lines WL, and the first and second gate upper lines UL1 and UL2 may be electrically connected to the decoder circuit 1110 via first connection wires 1115 extending from the first structure 1100F to the second structure 1100S. The bitline BL may be electrically connected to the page buffer 1120 via a second connection wires 1125 extending from the first structure 1100F to the second structure 1100S.

In the first structure 1100F, the decoder circuit 1110 and the page buffer 1120 may execute control operations on at least one memory cell transistor selected from the plurality of memory cell transistors MCTs. The decoder circuit 1110 and the page buffer 1120 may be controlled by the logic circuit 1130. The semiconductor device 1100 may communicate with the controller 1200 via an input/output pad 1101 electrically connected to the logic circuit 1130. The input/output pad 1101 may be electrically connected to the logic circuit 1130 via an input/output connection wire 1135 extending to the second structure 1100S within the first structure 1100F.

The controller 1200 may include a processor 1210, a NAND controller 1220, and a host interface 1230. The electronic system 1000 may include the plurality of semiconductor devices 1100, in which case the controller 1200 may control the plurality of semiconductor devices 1100.

The processor 1210 may control operations throughout the electronic system 1000 including the controller 1200. The processor 1210 may operate according to predetermined firmware and may control the NAND controller 1220 to access the semiconductor devices 1100. The NAND controller 1220 may include a NAND interface 1221 that processes communication with the semiconductor device 1100. Through the NAND interface 1221, control commands to control the semiconductor device 1100, data to be recorded to the memory cell transistors MCTs of the semiconductor device 1100, data to be read from the memory cell transistors MCTs of the semiconductor device 1100, and the like may be transmitted. The host interface 1230 may provide a communication function between the electronic system 1000 and an external host. Upon receiving control commands from the external host via the host interface 1230, the processor 1210 may control the semiconductor device 1100 in response to the control commands.

FIG. 45 is a perspective view schematically illustrating an electronic system including a semiconductor device, e.g., any of the semiconductor devices described with respect to FIGS. 1 to 44.

Referring to FIG. 45, an electronic system 2000 may include a main substrate 2001, a controller 2002 mounted on the main substrate 2001, one or more semiconductor packages 2003, and a DRAM 2004. The semiconductor package 2003 and the DRAM 2004 may be connected to the controller 2002 by a wiring pattern 2005 formed on the main substrate 2001.

The main substrate 2001 may include a connector 2006 including a plurality of pins that is coupled with an external host. The number and arrangement of the plurality of pins on the connector 2006 may vary depending on the communication interface between the electronic system 2000 and the external host. In some implementations, the electronic system 2000 communicates with the external host according to any of the interfaces including universal serial bus (USB), peripheral component interconnect express (PCI-Express), serial advanced technology attachment (SATA), M-Phy for universal flash storage (UFS), and others. In some implementations, the electronic system 2000 is operated by power supplied from an external host via the connector 2006. The electronic system 2000 may further include a power management integrated circuit (PMIC) that distributes power supplied from the external host to the controller 2002 and the semiconductor package 2003.

The controller 2002 may record data to the semiconductor package 2003, or read data from the semiconductor package 2003, and may improve the speed of operation of the electronic system 2000.

The DRAM 2004 may be a buffer memory to mitigate the speed difference between the semiconductor package 2003, which is a data storage space, and an external host. The DRAM 2004 included in the electronic system 2000 may also function as a type of cache memory, and may provide a space for temporarily storing data during control operations on the semiconductor package 2003. When the electronic system 2000 includes the DRAM 2004, the controller 2002 may further include a DRAM controller for controlling the DRAM 2004 in addition to the NAND controller for controlling the semiconductor package 2003.

The semiconductor package 2003 may include first and second semiconductor packages 2003a and 2003b that are spaced apart from each other. The first and second semiconductor packages 2003a and 2003b may each be a semiconductor package including a plurality of semiconductor chips 2200. Each of the first and second semiconductor packages 2003a and 2003b may include a package substrate 2100, a semiconductor chip 2200 on the package substrate 2100, an adhesive layer 2300 disposed on a bottom surface of each of the semiconductor chips 2200, a connection structure 2400 electrically connecting the semiconductor chips 2200 to the package substrate 2100, and a molding layer 2500 covering the semiconductor chip 2200 and the connection structure 2400 on the package substrate 2100.

The package substrate 2100 may be a printed circuit board including a package top pad 2130. Each semiconductor chip 2200 may include an input/output pad 2210. The I/O pads 2210 may correspond to the input/output pad 1101 of FIG. 46. Each of the semiconductor chips 2200 may include a gate stack structure 3210 and a channel structure 3220. The semiconductor chips 2200 may each include the semiconductor device described with reference to FIGS. 1 to 15.

FIG. 47 is a cross-sectional view schematically illustrating a semiconductor package according to some implementations.

Referring to FIG. 47, in a semiconductor package 2003A, each of semiconductor chips 2200a may include a semiconductor substrate 4010, a first structure 4100 on the semiconductor substrate 4010, and a second structure 4200 bonded to the first structure 4100 by a wafer bonding method on the first structure 4100. The semiconductor chips 2200a may include semiconductor devices as described with respect to FIGS. 1 to 44.

The first structure 4100 may include a peripheral circuit area including peripheral wires 4110 and first junction structures 4150. The second structure 4200 may include a common source line 4205, a gate stack structure 4210 between the common source line 4205 and the first structure 4100, a channel structure 4220 and a separation structure 4230 penetrating the gate stack structure 4210, and second junction structures 4250 electrically connected to the wordlines (see “WL” in FIG. 46, hereinafter the same) of the channel structure 4220 and the gate stack structure 4210, respectively. For example, the second junction structures 4250 may be electrically connected to the channel structure 4220 and the wordline WL, respectively, via the bitlines 4240 electrically connected to the channel structures 4220 and the gate connection wires electrically connected to the wordlines WL. The first junction structure 4150 of the first structure 4100 and the second junction structure 4250 of the second structure 4200 may be bonded while being in contact with each other. The bonding portions of the first junction structure 4150 and the second junction structure 4250 may be formed of, for example, copper (Cu).

In the semiconductor chip 2200a, the separation structure 300 has a zigzag shape along the second direction (Y direction) such that the separation structure 300 overlaps the channel structure CH in the third direction (Z direction), so that a margin overlapping the channel structure CH in the third direction (Z direction) may be secured in the process of forming the separation structure 300.

Each of the semiconductor chips 2200a may further include an input/output pad 2210 and an input/output connection wire 4265 below the input/output pad 2210. The input/output connection wire 4265 may be electrically connected to a portion of the second junction structure 4250.

The plurality of semiconductor chips 2200 in the semiconductor package 2003 may be electrically connected to each other by the connection structures 2400 in the form of bonding wires. As another example, the plurality of semiconductor chips 2200 or a plurality of portions configuring the plurality of semiconductor chips 2200 may be electrically connected by a connection structure including through electrodes.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

Although various example have been described in detail, the scope of the present disclosure is not limited to those examples. Various changes and modifications using the basic concept of the present disclosure defined in the accompanying claims by those skilled in the art shall be construed to belong to the scope of the present disclosure.

What is claimed is:

1. A semiconductor device comprising:
a peripheral circuit structure and a cell structure stacked on the peripheral circuit structure,
wherein the peripheral circuit structure includes a first substrate on which circuit elements are arranged,
wherein the cell structure includes
a second substrate including a first surface facing the first substrate and a second surface opposite the first surface,
a gate stack structure including a plurality of interlayer insulating layers and a plurality of gate electrodes alternately stacked on the first surface of the second substrate,
a plurality of channel structures extending into the gate stack structure, and
a separation structure extending from the first surface of the second substrate into at least a portion of the channel structure and into at least a portion of the plurality of gate electrodes, and
wherein the separation structure has a zigzag shape extending along a first direction and a second direction intersecting the first direction.

2. The semiconductor device of claim 1, wherein the separation structure includes:
a first extending portion extending in the first direction;
a second extending portion extending in the second direction; and
a bent portion located between the first extending portion and the second extending portion, the bent portion overlapping a first channel structure of the plurality of channel structures along a thickness direction of the second substrate.

3. The semiconductor device of claim 2, wherein the first extending portion and the second extending portion are arranged alternately along a third direction intersecting the first direction and the second direction, wherein the third direction is a direction in a plane defined by the first direction and the second direction.

4. The semiconductor device of claim 2, wherein the plurality of gate electrodes includes ground gate electrodes located in an upper portion of the gate stack structure, and
wherein the separation structure extends into the ground gate electrodes.

5. The semiconductor device of claim 4, wherein:
the ground gate electrodes include first portions and second portions spaced apart in the first direction by the separation structure,
the first extending portion includes a first lateral surface facing the first portions, and a second lateral surface opposite the first lateral surface, and
the first lateral surface and the second lateral surface extend parallel to one another.

6. The semiconductor device of claim 2, wherein a point at which the first extending portion and the second extending portion meet overlaps a center of the first channel structure along the thickness direction of the second substrate.

7. The semiconductor device of claim 2, wherein a lateral surface of the bent portion has a curved surface.

8. The semiconductor device of claim 7, wherein the lateral surface of the bent portion is in contact with the first channel structure.

9. The semiconductor device of claim 2, wherein a length of the first extending portion along the first direction is equal to a length of the second extending portion along the second direction.

10. The semiconductor device of claim 2, wherein a length of the first extending portion along the first direction is equal to or less than a distance between respective centers of channel structures, of the plurality of channel structures, that are adjacent in the first direction.

11. The semiconductor device of claim 10, wherein a width of the first extending portion along a third direction intersecting the first direction and the second direction is equal to a width along the third direction of the second extending portion.

12. The semiconductor device of claim 1, wherein the a first channel structure of the plurality of channel structures includes:
a channel layer;
a tunneling layer surrounding the channel layer;
a charge storage layer surrounding the tunneling layer; and
a blocking layer arranged between the charge storage layer and the plurality of gate electrodes,
wherein the separation structure extends into at least a portion of the channel layer.

13. The semiconductor device of claim 12, wherein the second substrate includes:
a common source electrode connected to the channel layer; and
an insulating pattern located on the common source electrode,
wherein a top surface of the separation structure is in contact with the common source electrode.

14. The semiconductor device of claim 1, comprising a plurality of separation patterns extending into the gate stack structure,
wherein the plurality of separation patterns extend along an extension direction of the separation structure and are spaced apart from the separation structure.

15. The semiconductor device of claim 14, further comprising a select separation pattern extending into at least a portion of the gate stack structure between the plurality of separation patterns,
wherein the select separation pattern extends along the extension direction of the separation structure and is spaced apart from the separation structure.

16. A semiconductor device comprising:
a peripheral circuit structure and a cell structure stacked on the peripheral circuit structure,
wherein the peripheral circuit structure includes a first substrate on which circuit elements are arranged,
wherein the cell structure includes:
a second substrate including a first surface facing the first substrate and a second surface opposite the first surface,
a gate stack structure including a plurality of interlayer insulating layers and a plurality of gate electrodes alternately stacked on the first surface of the second substrate, wherein the plurality of gate electrodes include ground gate electrodes,
a plurality of channel structures extending into the gate stack structure, and
a separation structure extending from the first surface of the second substrate into at least a portion of a first channel structure of the plurality of channel structures, the separation structure separating the ground gate electrodes into first portions and second portions,
wherein the separation structure includes:
a first extending portion extending in a first direction along a plane of the second surface of the second substrate, and
a second extending portion extending in the plane in a second direction intersecting the first direction, and
wherein a point at which the first extending portion and the second extending portion meet overlaps the first channel structure along a thickness direction of the second substrate.

17. The semiconductor device of claim 16, wherein the first extending portion includes a first lateral surface facing the first portions and a second lateral surface facing the second portions.

18. The semiconductor device of claim 16, wherein:
the first extending portion and the second extending portion are arranged alternately along a third direction in the plane, the third direction intersecting the first direction and the second direction.

19. An electronic system comprising:
a main substrate;
a semiconductor device on the main substrate; and
a controller electrically connected to the semiconductor device,
wherein the semiconductor device includes:
a peripheral circuit structure including a first substrate,
a cell structure stacked on the peripheral circuit structure and including input and output connection wires electrically connected to the peripheral circuit structure, and
an input/output pad electrically connected to the input/output connection wires,
wherein the cell structure includes:
a second substrate including a first surface facing the first substrate and a second surface opposite the first surface,
a gate stack structure including a plurality of interlayer insulating layers and a plurality of gate electrodes alternately stacked on the first surface of the second substrate,
a plurality of channel structures extending into the gate stack structure, and
a separation structure extending from the first surface of the second substrate into at least a portion of a first channel structure of the plurality of channel structures and into at least a portion of the plurality of gate electrodes, and
wherein the separation structure has a zigzag shape extending along a first direction and a second direction intersecting the first direction.

20. The electronic system of claim 19, wherein the separation structure includes:
a first extending portion extending in the first direction; and
a second extending portion extending in the second direction,
wherein a point at which the first extending portion and the second extending portion meet overlaps the first channel structure in a thickness direction of the first substrate.
